(19) United States
(12) Patent Application Publication
(10) Pub. No.: US 2023/0345764 A1
(43) Pub. Date: Oct. 26, 2023

(54) DISPLAY DEVICE

(71) Applicant: Samsung Display Co., Ltd., Yongin-si (KR)

(72) Inventors: KYUNGHOE LEE, Yongin-si (KR); JI-SUN KIM, Yongin-si (KR); YOUNGWAN SEO, Yongin-si (KR); KEUNHEE CHOI, Yongin-si (KR)

(73) Assignee: Samsung Display Co., Ltd., Yongin-si (KR)

(21) Appl. No.: 18/113,294

(22) Filed: Feb. 23, 2023

(30) Foreign Application Priority Data
Apr. 22, 2022 (KR) 10-2022-0050422

(51) Int. Cl. H10K 59/121; H10K 59/131

(52) U.S. Cl. CPC H10K 59/1213; H10K 59/131

(57) ABSTRACT

Provided is a display device including a display panel including a display region and a non-display region adjacent to the display region, the display region including a first display region, and a second display region more adjacent to the non-display region than the first display region, and including an edge region and a corner region, the edge region and the corner region each including a first region and a second region continuously defined, wherein the display panel includes a first pixel disposed in the first display region, a second pixel disposed in the second display region, and a driving part disposed in the second region, the driving part includes a first driving part disposed in the edge region and a second driving part disposed in the corner region, and a shape of the first driving part and a shape of the second driving part are different from each other.

### CROSS-REFERENCE TO RELATED APPLICATION(S)

This application claims priority to and benefits of Korean Patent Application No. 10-2022-0050422 under 35 U.S.C. § 119, filed on Apr. 22, 2022, in the Korean Intellectual Property Office, the entire contents of which are incorporated herein by reference.

### BACKGROUND

### 1. Technical Field

The disclosure herein relates to a display device with a reduced bezel.

### 2. Description of the Related Art

Multimedia electronic devices such as televisions, mobile phones, tablet computers, computers, navigation system units, and game consoles are equipped with a display panel for displaying images.

Recently, in response to the demand in the market, research is underway to reduce a region in which an image is not displayed in a display panel. At the same time, research is underway to expand display region in which an image is displayed to a user and reduce a bezel in the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device with a reduced bezel.

The disclosure also provides a display device in which the placement and shape of a driver disposed in a corner region of a display panel may be designed differently from the placement and shape of a driver disposed in an edge region thereof, so that an inner space in which pixels are disposed is secured and a bezel may be reduced in size.

An embodiment provides a display device which may include a display panel including a display region, and a non-display region adjacent to the display region, the display region may include a first display region, and a second display region more adjacent to the non-display region than the first display region, and may include an edge region and a corner region, the edge region and the corner region each includes a first region and a second region continuously defined, wherein the display panel may include a first pixel disposed in the first display region, a second pixel disposed in the second display region, and a driving part disposed in the second region, the driving part may include a first driving part disposed in the edge region and a second driving part disposed in the corner region, and a shape of the first driving part and a shape of the second driving part may be different from each other.

In an embodiment, the display panel may further include a base layer, a circuit layer disposed on the base layer, and including a first pixel driving circuit overlapping the first di splay region in a plan view, a second pixel driving circuit overlapping the first region in a plan view, and a driver overlapping the second region in a plan view, and a light emission element layer disposed on the circuit layer, and including a first light emission region overlapping the first display region in a plan view and a second light emission region overlapping the second display region in a plan view.

In an embodiment, the first pixel may be electrically connected to the first pixel driving circuit, and the second pixel may be electrically connected to the second pixel driving circuit.

In an embodiment, the second pixel may be disposed in the first region and in the second region, and the second pixel disposed in the first region and the second pixel disposed in the second region may both be electrically connected to the second pixel driving circuit disposed in the first region.

In an embodiment, an area of the second light emission region may be greater than an area of the corresponding first light emission region.

In an embodiment, the first driving part may have a first length in a first direction, the second driving part may have a second length in the first direction, and the first length may be greater than the second length.

In an embodiment, the first driving part may have a third length in a second direction intersecting the first direction, the second driving part may have a fourth length in the second direction, and the third length may be less than the fourth length.

In an embodiment, the first driving part and the second driving part may each include a first driver, a second driver, and third drivers.

In an embodiment, the first driver and the second driver may be disposed adjacent to each other in a first direction, and the third drivers may be disposed adjacent to each other in a second direction intersecting the first direction.

In an embodiment, the second driver and the third drivers may be disposed adjacent in the first direction.

In an embodiment, a maximum length in the second direction of each of the first driver, the second driver, and the third drivers of the first driver may all be equal to each other.

In an embodiment, the maximum length in the second direction of the first driver of the second driving part may be greater than the maximum length in the second direction of the second driver of the second driving part, and the maximum length in the second direction of the second driver of the second driving part may be greater than the maximum length in the second direction of the third drivers of the second driving part.

In an embodiment, the driving part may further include a first driving line electrically connected to the first driving part, at least one second driving line extended from the first driving line and electrically connected to the second driving part, and the second driving line may be disposed farther from the first display region than the first driving line.

In an embodiment, the at least one second driving line may include second driving lines, and among the second driving lines, a second driving line adjacent to the first display region may be disposed farther from the first display region than the first driving line.

In an embodiment, a display device may include a display panel in which a display region and a non-display region adjacent to the display region are defined on a plane, wherein the display region may include a first display region, and a second display region more adjacent to the non-display region than the first display region, and may include an edge region and a corner region, wherein the edge region and the corner region each may include a first region in which a light emission element and a pixel driving circuit electrically connected to the light emission element may be disposed, a second region in which a driving part may be disposed, and a length in a first direction of the second region defined in the edge region may be greater than a length in the first direction of the second region defined in the corner region.

In an embodiment, a length in the first direction of the first region defined in the edge region may be less than a length in the first direction of the first region defined in the corner region.

In an embodiment, the driving par may include a first driving part disposed in the edge region and a second driving part disposed in the corner region, and a first length in the first direction of the first driving part may be greater than a second length in the first direction of the second driving part by a third length.

In an embodiment, the length in the first direction of the second region defined in the edge region may be greater than the length in the first direction of the second region defined in the corner region by the third length.

In an embodiment, the maximum length in a second direction intersecting the first direction of the first driving part may be less than the maximum length in the second direction of the second driving part.

In an embodiment, the display panel may include a base layer, a circuit layer disposed on the base layer, and having the pixel driving circuit and the driving part disposed therein, and a light emission element layer disposed on the circuit layer, and including the light emission element.

In an embodiment, in the corner region, the first region may include a first sub-region and a second sub-region defined between the first sub-region and the second region, and the pixel driving circuit may be disposed in the first sub-region.

In an embodiment, a distance from the first display region to an outer boundary line of the second region in the edge region may be substantially equal to a distance from the first display region to an outer boundary line of the second region in the corner region, and a distance from the first display region to an inner boundary line of the second region in the corner region may be greater than a distance from the first display region to an inner boundary line of the second region in the edge region.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1 is a schematic perspective view of a display device according to an embodiment;

FIG. 2 is an exploded schematic perspective view of a display device according to an embodiment;

FIG. 3A and FIG. 3B are each schematic plan views of a display panel according to an embodiment;

FIG. 4 is a schematic diagram of an equivalent circuit of a pixel according to an embodiment;

FIG. 5A is a schematic cross-sectional view of a portion of a display panel according to an embodiment;

FIG. 5B is a schematic cross-sectional view of a portion of a display panel according to an embodiment;

FIG. 6A is an enlarged schematic plan view of region A1 illustrated in FIG. 3;

FIG. 6B and FIG. 6C are each enlarged schematic plan views of region A3 illustrated in FIG. 6A;

FIG. 7 is an enlarged schematic plan view of region A2 illustrated in FIG. 3;

FIG. 8 is a schematic view showing the comparison of an edge region and a corner region according to an embodiment;

FIG. 9A is a schematic view showing a first driver according to an embodiment;

FIG. 9B is a schematic view showing a second driver according to an embodiment; and

FIG. 10A and FIG. 10B are each schematic views of a second driver according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

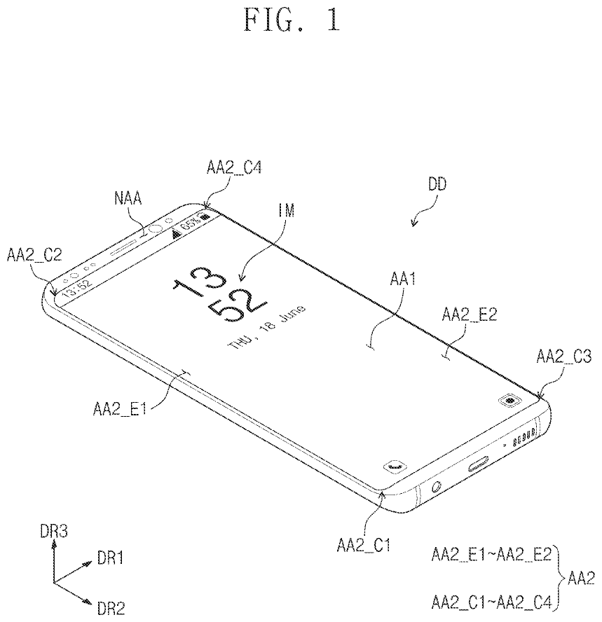

FIG. 1 is a schematic perspective view of a display device according to an embodiment.

In FIG. 1, the display device DD is illustrated as being a mobile phone. However, the embodiment is not limited thereto, and the display device DD may be large electronic devices such as televisions and monitors, or small-and-medium-sized electronic devices such as tablet computers, laptops, car navigation system units, game consoles, and smart watches.

In the display device DD, active regions AA1 and AA2 in which an image IM is displayed and a peripheral region NAA in which the image IM is not displayed may be defined. In FIG. 1, as an example of the image IM, date and time images are illustrated.

The active regions AA1 and AA2 may include a first active region AA1 having a planar shape and a second active region AA2 bent from the first active region AA1. The second active region AA2 may be a region bent from the first active region AA1 to a curvature (e.g., a predetermined or selectable curvature). However, the shape of the second active region AA2 is not limited thereto. For example, the second active region AA2 may be bent from the first active region AA1 and may have a planar shape inclined or perpendicular to the first active region AA1. The first and second active regions AA1 and AA2 may be regions only structurally separated and may implement substantially one display surface. The peripheral region NAA may be a region in which the image IM is not displayed. A bezel region of the display device DD may be defined by the peripheral region NAA. In some portions of the second active region AA2, an image may not be displayed. For example, the bezel region may be defined along the edge in the second active region AA2.

The first active region may be parallel to a plane defined by a first direction DR1 and a second direction DR2. A normal direction of the first active region AA1, that is, a thickness direction of the display device DD may be parallel to a third direction DR3. A front surface (or an upper surface) and a back surface (or a lower surface) of each member of the display device DD may be separated by the third direction DR3. However, directions indicated by the first to third directions DR1, DR2, and DR3 are a relative concept, and may be converted to different directions.

The second active region AA2 may be a region extended in the direction of the peripheral region NAA from the first active region AA1. The second active region AA2 may include edge active regions AA2_E1 to AA2_E2 extended from side edges of the first active region AA1 and corner active regions AA2_C1 to AA2_C4 extended from corners of the first active region AA1. The second active region AA2 may include a first edge active region AA2_E1 extended from a first side of the first active region AA1 and a second edge active region AA2-E2 extended from a second side of the first active region AA1. The second active region AA2 may include a first corner active region AA2_C1 extended from a first corner of the first active region AA1, a second corner active region AA2_C2 extended from a second corner of the first active region AA1, a third corner active region AA2_C3 extended from a third corner of the first active region AA1, and a fourth corner active region AA2_C4 extended from a fourth corner of the first active region AA1.

The first corner active region AA2_C1 may be disposed at one end of the first edge active region AA2_E1, and the second corner active region AA2_C2 may be disposed at the other end of the first edge active region AA2_E1. The third corner active region AA2_C3 may be disposed at one end of the second edge active region AA2_E2, and the fourth corner active region AA2_C4 may be disposed at the other end of the second edge active region AA2_E2.

The number of the edge active regions AA2_E1 to AA2_E2 and the number of the corner active regions AA2_C1 to AA2_C4 are not limited thereto. For example, depending on the shape of the first active region AA1, the number of the edge active regions AA2_E1 to AA2_E2 and the number of the corner active regions AA2_C1 to AA2_C4 included in the second active region AA2 may vary.

In an embodiment, a first image displayed in the first active region AA1 and a second image displayed in the second active region AA2 may be dependent on each other. For example, a combination of the first image and the second image may form one picture, one scene of a movie, or a UI/UX design. Due to the second active region AA2 bent to have a curvature, the aesthetic feel of the display device DD may be improved, and the area of the peripheral region NAA recognized by a user may be reduced.

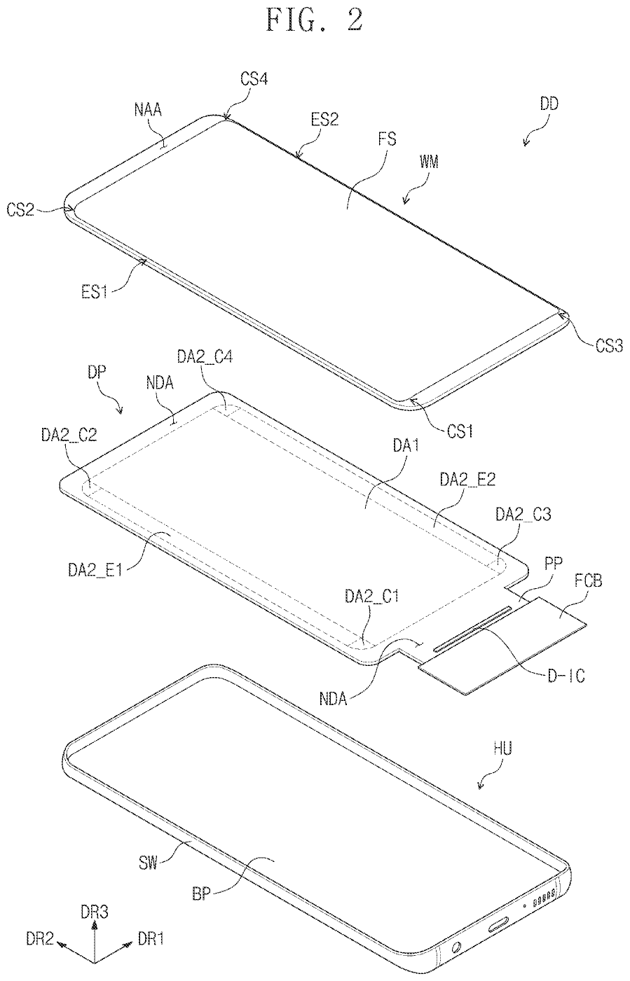

FIG. 2 is an exploded schematic perspective view of a display device according to an embodiment.

Referring to FIG. 2, the display device DD may include a window WM, a display panel DP, and a housing HU. The window WM protects an upper surface of the display panel DP. The window WM may be optically transparent. Accordingly, an image displayed in the display panel DP may transmit the window WM and be visible to a user. For example, a display surface of the display device DD may be defined by the window WM. The window WM may be composed of glass, plastic, or a film.

The window WM may have straight line shapes and curved line shapes. The window WM may include a front surface part FS and one or more corner parts CS1 to CS4 extended from the front surface part FS. Here, the front surface part FS and the one or more corner parts CS1 to CS4 may be defined as transmissive portions which transmit an image or light. The front surface part FS of the window WM may define the first active region AA1 (see FIG. 1) of the display device DD, and the one or more corner parts CS1 to CS4 may define the corner active regions AA2_C1 to AA2_C4 in the second active region AA2 (see FIG. 1).

In an embodiment, the window WM may include two edge portions, that is, a first edge portion ES1 and a second edge portion ES2. In an embodiment, the front surface part FS may be a plane defined by the first direction DR1 and the second direction DR2. The front surface part FS may be perpendicular to the third direction DR3.

The first edge portion ES1 and the second edge portion ES2 may be respectively extended from the front part FS to both sides in the first direction DR1. The first and second edge portions ES1 and ES2 may be respectively extended from first and second sides of the front surface part FS. The first and second sides of the front surface part FS may be parallel to the first direction DR1. The first edge portion ES1 and the second edge portion ES2 may be defined as being parallel to each other in the first direction DR1. The first and second portions ES1 and ES2 may be extended in a straight line in the second direction DR2. The first and second portions ES1 and ES2 may be referred to as straight line portions.

The window WM may further include at least one corner part. In an embodiment, the window WM may include 4 corner parts, For example, a first corner part CS1, a second corner part CS2, a third corner part CS3, and a fourth corner part CS4. The first to fourth corner parts CS1 to CS4 may each have a curvature on a plane defined by the first direction DR1 and the second direction DR2. The first to fourth corner parts CS1 to CS4 may each be referred to as a curved line portion.

The first corner part CS1 and the second corner part CS2 may be respectively disposed at one end and the other end of the first edge portion ES1. The third corner part CS3 and the fourth corner part CS4 may be respectively disposed at one end and the other end of the second edge portion ES2. Here, the first to fourth corner parts CS1 to CS4 may each be defined as a transmissive portion which transmits an image or light.

The display panel DP may further include a pad region PP extended from a second display region DA2. In the pad region PP of the display panel DP, a driving chip D-IC and pads may be disposed. The driving chip D-IC may provide a driving signal to first and second display regions DA1 and DA2 of the display panel DP. The driving chip D-IC may be mounted on the display panel DP. The display panel DP may be electrically connected to a printed circuit board FCB through the pads. In an embodiment, the driving chip D-IC may be mounted on the printed circuit board FCB.

The housing HU may include a bottom portion BP and a sidewall SW. The sidewall SW may be extended from the bottom portion BP. The housing HU may accommodate the display panel DP in an accommodation space defined by the bottom portion BP and the sidewall SW. The window WM may be coupled to the sidewall SW of the housing HU. The sidewall SW of the housing HY may support an edge of the window WM.

The housing HU may include a material having relatively high rigidity. For example, the housing HU may include glass, plastic, or a metal, or may include multiple frames and/or plates composed of a combination thereof. The housing HU may stably protect the components of the display device DD received in the internal space from an external impact.

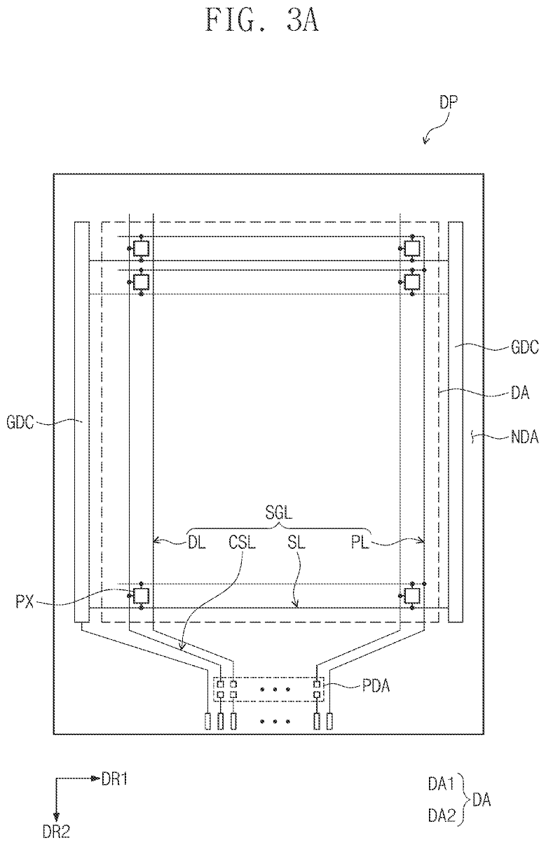

FIG. 3A and FIG. 3B are each schematic plan views of a display panel according to an embodiment.

Referring to FIG. 3A, the display panel DP may include a driving part GDC, signal lines SGL (hereinafter, signal lines) and pixels PX (hereinafter, pixels).

The driving part GDC may include a scan driving circuit. The scan driving circuit may generate multiple scan signals (hereinafter, scan signals), and outputs the scan signals to multiple scan lines SL (hereinafter, scan lines) to be described later. The scan driving circuit may further output another control signal to a driving circuit of the pixels PX.

The scan driving circuit may include transistors formed through the same process as that of the driving circuit of the pixels PX, for example, a low temperature polycrystalline silicon (LTPS) process or a low temperature polycrystalline oxide (LTPO) process.

The signal lines SGL may include scan lines SL, data lines DL, a driving voltage line PL, and a control signal line CSL. Each of the scan lines SL may be connected to a corresponding pixel PX among the pixels PX, and each of the data lines DL may be connected to a corresponding pixel PX among the pixels PX. The driving voltage line PL may be connected to the pixels PX. The control signal line CSL may provide control signals to the scan driving circuit.

FIG. 3A illustrates a mounting region PDA of the display panel DP in which the driving chip D-IC (see FIG. 2) in the form of a chip is disposed. The driving chip D-IC may be connected to the data lines DL.

Referring to FIG. 3B, the display panel DP may include a display region which displays an image. In an embodiment, the display region may include the first display region DA1 and the second display region DA2. The first display region DA1 may be disposed parallel to the front surface part FS of the window WM, and may have a shape corresponding to the front surface part FS. For example, the first display region DA1 may be a center display region corresponding to the front surface part FS in the display region. The second display region DA2 may be disposed corresponding to one or more edge portions ES1 and ES2 (see FIG. 2) and one or more corner parts CS1 to CS4 (see FIG. 2). The second display region DA2 may have a shape formed of a straight line and a curved line respectively corresponding to the one or more edge portions ES1 and ES2 and the one or more corner parts CS1 to CS4.

The second display region DA2 may include first and second edge regions DA2_E1 to DA2_E2 disposed respectively corresponding to the first and second edge portions ES1 and ES2. The first and second edge regions DA2_E1 and DA2_E2 may be extended to first and second sides in the first display region DA1, and may be disposed respectively corresponding to the first and second edge portions ES1 and ES2 of the window WM. Here, the first and second sides may be extended parallel to the first direction DR1. The first and second edge regions DA2_E1 and DA2_E2 may correspond to a straight line region having a straight line shape in the second direction DR2.

In the above, a structure in which the second display region DA2 includes two edge regions DA2_E1 and DA2_E2 in the display panel DP according to an embodiment has been described. However, the structure of the display panel DP according to embodiments is not limited thereto. The second display region DA2 may only include two edge regions provided on third and fourth sides of the first display region DA1. The second display region DA2 of the display panel DP may include four edge regions provided on all of the first to fourth sides of the first display region DA1.

The second display region DA2 may include first to fourth corner regions DA2_C1 to DA2_C4 disposed respectively corresponding to the first to fourth corner parts CS1 to CS4 of the window WM. The first corner region DA2_C1 and the second corner region DA2_C2 may be disposed at one end and the other end of the first edge region DA2_E1. The third corner region DA2_C3 and the fourth corner region DA2_C4 may be disposed at one end and the other end of the second edge region DA2_E2. The first to fourth corner regions DA2_C1 to DA2_C4 may be regions in which an image is substantially displayed. However, the embodiment of the inventive concept is not limited thereto. As another example, the first to fourth corner regions DA2_C1 to DA2_C4 may be regions which do not display an image, and only some thereof may display an image.

The first to fourth corner regions DA2_C1 to DA2_C4 may have a curved line shape in a diagonal direction defined between the first direction DR1 and second direction DR2. The first to fourth corner regions DA2_C1 to DA2_C4 may be referred to as curved line regions.

The display panel DP may include first pixels disposed in the first display region DA1 and second pixels disposed in the second display region DA2. The first and second pixels PX may each include a light emitting element and a pixel driving circuit connected thereto.

The display panel DP may further include a plurality of driving parts GDC. The plurality of the driving parts GDC1 and GDC2 may each include a first driving part GDC1 and a second driving part GDC2. The first driving part GDC1 may be disposed in the edge regions DA2_E1 and DA2_E2 and the second driving part GDC2 may be disposed in the corner regions DA2_C1 to DA2_C4.

Each of the first and second driving parts GDC1 and GDC2 may generate scan signals and light emission control signals, and may output the generated signals to corresponding pixels. The first driving part GDC1 and the second driving part GDC2 will be described in detail later.

The display panel DP may further include a non-display region NDA around the second display region DA2. The non-display region NDA may be substantially a region in which an image is not displayed. The non-display region NDA may surround the second display region DA2.

The plurality of driving parts GDC may be disposed in the second display region DA2 or disposed to partially overlap the second display region DA2. In case that the plurality of driving parts GDC are disposed in the second display region DA2, it may be possible to prevent the width of the non-display region NDA from increasing by the driving parts GDC. For example, the area of the non-display region NDA recognized by a user in the display device DD may be reduced by the second display region DA2. In an embodiment, the driving parts GDC may each include a scan driver and a light emission driver. In an embodiment, the first driving part GDC1 and the second driving part GDC2 may each include a scan driver for driving scan lines and a light emission driver for driving light emission control lines.

In an embodiment, a first image displayed in the first region DA1 and a second image displayed in the second region DA2 may be dependent on each other. For example, a combination of the first image and the second image may form one picture, one scene of a movie, or a UI/UX design. However, the embodiment is not limited thereto. For example, some display regions of the second display region DA2, for example, the first to fourth corner regions DA2_C1 to DA2_C4 may display a black image not dependent on the first image or a pattern image.

In an embodiment, the display panel DP may be an organic emitting display panel, an electrophoretic display panel, or an electro wetting display panel. The display panel DP may be a flexible display panel which may be bent according to the shape of the window WM.

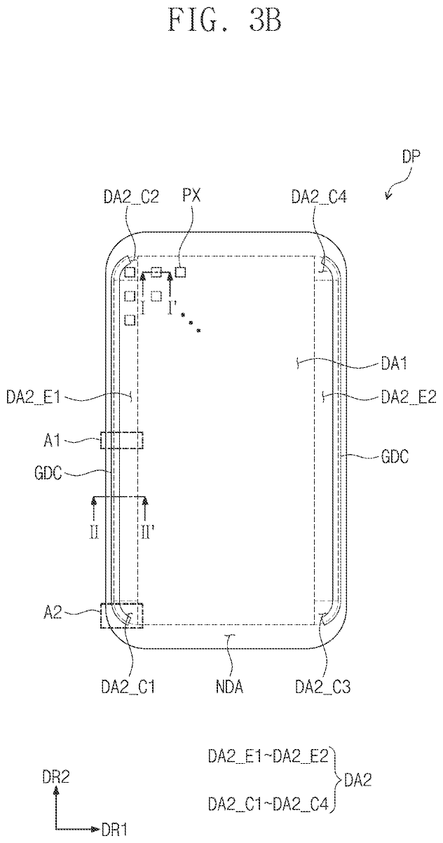

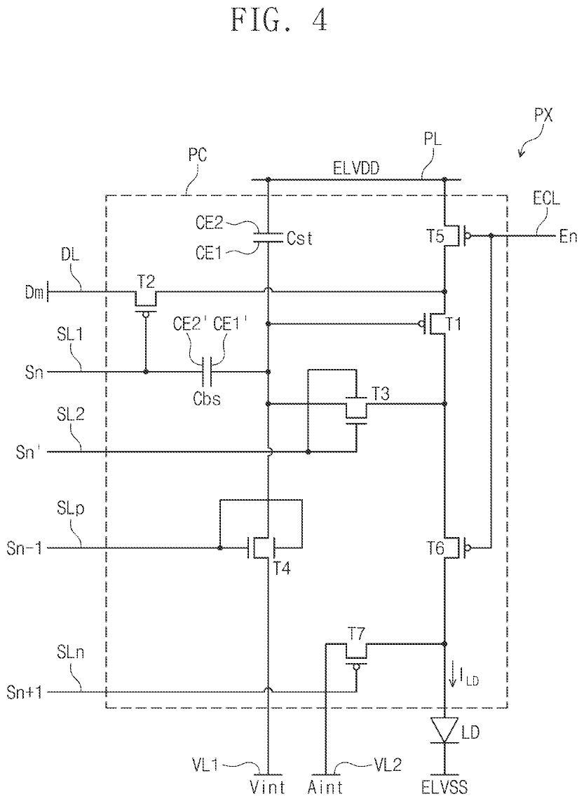

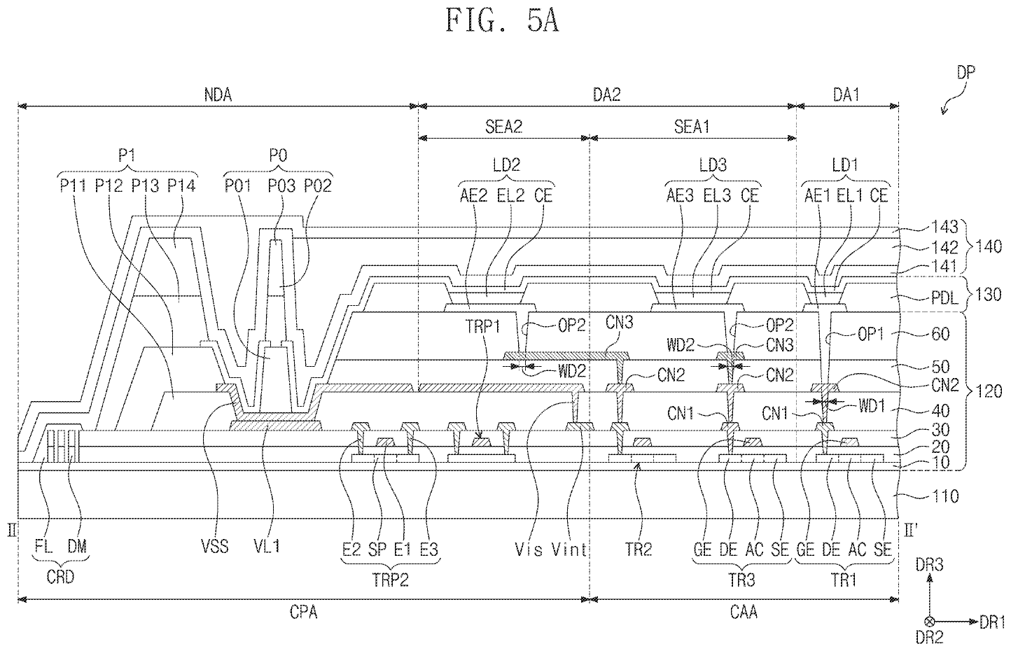

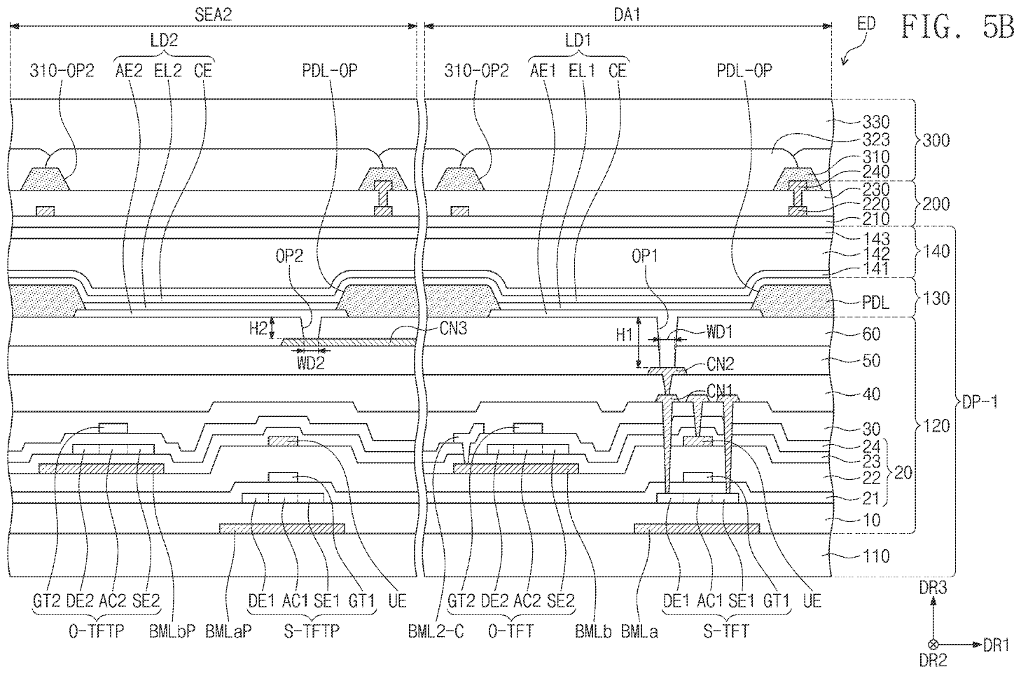

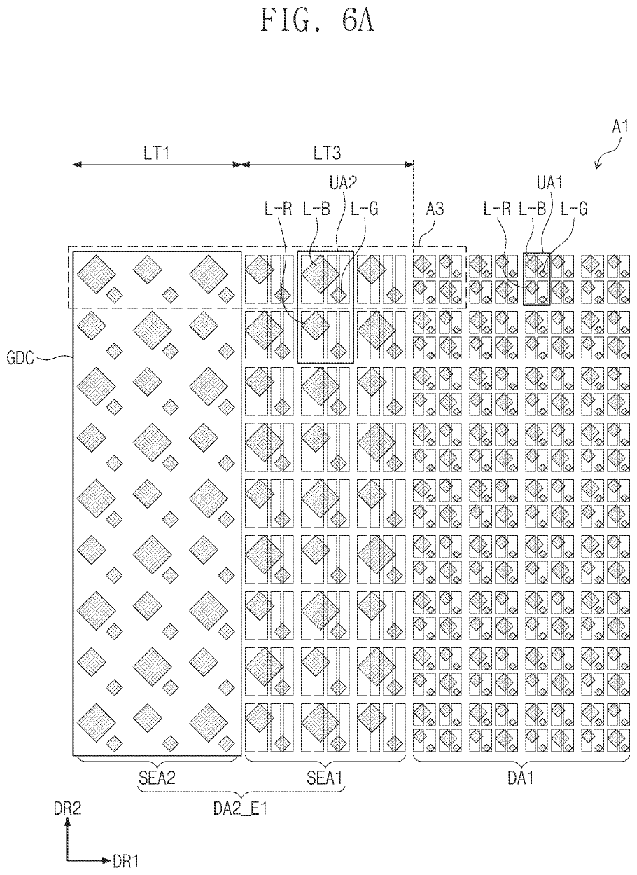

FIG. 4 is a schematic diagram of an equivalent circuit of a pixel PX according to an embodiment. FIG. 5A and FIG. 5B are each schematic cross-sectional views of portions of a display panel according to an embodiment. FIG. 6A is an enlarged schematic plan view of region A1 illustrated in FIG. 3B. FIG. 6B and FIG. 6C are each enlarged schematic plan views of region A3 illustrated in FIG. 6A. Hereinafter, a pixel according to an embodiment will be described with reference to FIG. 4 to FIG. 6B. With reference to FIG. 6C, a driver will be described.

Referring to FIG. 4, a schematic diagram of an equivalent circuit of one pixel PX is illustrated. Multiple pixels PX of FIG. 4 may be provided. The pixel PX may include a first pixel PX1 disposed in the first display region DA1 and a second pixel PX2 and a third pixel PX3 disposed in the first edge region DA2_E1.

The pixel PX may include a light emission element LD and a pixel circuit PC. The pixel circuit PC may include thin film transistors T1 to T7 and a storage capacitor Cst. The thin film transistors T1 to T7 and the storage capacitor Cst may be electrically connected to signal lines SL1, SL2, SLp, SLn, EL, and DL, a first initialization voltage line VL1, a second initialization voltage line VL2 (or an anode initialization voltage line), and a driving voltage line PL. In an embodiment, at least one of the above-described lines, for example, the driving voltage line PL, may be shared by neighboring pixels PX.

The thin film transistors T1 to T7 may include a driving thin film transistor T1, a switching thin film transistor T2, a compensation thin film transistor T3, a first initialization thin film transistor T4, an operation control thin film transistor T5, a light emission control thin film transistor T6, and a second initialization thin film transistor T7.

The light emission element LD may include a first electrode (e.g., an anode or a pixel electrode) and a second electrode (e.g., a cathode or a common electrode), and the first electrode of the light emission element LD may be connected to the driving thin film transistor T1 by means of the light emission control thin film transistor T6 and provided with a driving current ILD, and the second electrode may be provided with a low power voltage ELVSS. The light emission element LD may generate light of luminance corresponding to the driving current ILD.

Some of the thin film transistors T1 to T7 may be provided as n-channel MOSFETs (NMOS), and the others thereof may be provided as p-channel MOSFETs (PMOS). For example, among the thin film transistors T1 to T7, the compensation thin film transistor T3 and the first initialization thin film transistor T4 may be provided as n-channel MOSFETs (NMOS), and the rest may be provided as p-channel MOSFETs (PMOS).

In another embodiment, among the thin film transistors T1 to T7, the compensation thin film transistor T3, the first initialization thin film transistor T4, and the second initialization thin film transistor T7 may be provided as NMOSs, and the rest may be provided as PMOSs. In another embodiment, only one of the thin film transistors T1 to T7 may be provided as an NMOS, and the rest may be provided as PMOSs. In still another embodiment, all of the thin film transistors T1 to T7 may be provided as NMOSs, or all thereof may be provided as PMOSs.

The signal lines may include a first scan line SL1 which transmits a first scan signal Sn, a second scan line SL2 which transmits a second scan signal Sn′, a previous scan line SLp which transmits a previous scan signal Sn−1 to the first initialization thin film transistor T4, a light emission control line ECL which transmits a light emission control signal En to the operation control thin film transistor T5 and the light emission control thin film transistor T6, a next scan line SLn which transmits a next scan signal Sn+1 to the second initialization thin film transistor T7, and a data line DL which crosses the first scan line SL1 and transmits a data signal Dm.

The driving voltage line PL may transmit a driving voltage ELVDD to the driving thin film transistor T1, and the first initialization voltage line VL1 may transmit an initialization voltage Vint which initializes the driving thin film transistor T1 and a pixel electrode.

A driving gate electrode of the driving thin film transistor T1 may be connected to the storage capacitor Cst, a driving source region of the driving thin film transistor T1 may be connected to the driving voltage line PL via the operation control thin film transistor T5, a driving drain region of the driving thin film transistor T1 may be electrically connected to the first electrode of the light emission element LD via the light emission control thin film transistor T6. The driving thin film transistor T1 may receive the data signal Dm in accordance with a switching operation of the switching thin film transistor T2 and supply the driving current LD to the light emission element ED.

A switching gate electrode of the switching thin film transistor T2 may be connected to the first scan line SL1 which transmits the first scan signal Sn, a switching source region of the switching thin film transistor T2 may be connected to the data line DL, and a switching drain region of the switching thin film transistor T2 may be connected to the driving source region of the driving thin film transistor T1 and may be connected to the driving voltage line PL via the operation control thin film transistor T5. The switching thin film transistor T2 may be turned on in accordance with the first scan signal Sn received through the first scan line SL1 and may perform a switching operation of transmitting the data signal Dm transmitted through the data line DL to the driving source region of the driving thin film transistor T1.

A compensation gate electrode of the compensation thin film transistor T3 may be connected to the second scan line SL2. A compensation drain region of the compensation thin film transistor T3 may be connected to the driving drain region of the driving thin film transistor T1 and may be connected to a pixel electrode of the light emission element LD via the light emission control thin film transistor T6. A compensation source region of the compensation thin film transistor T3 may be connected to a first electrode CE1 of the storage capacitor Cst and to the driving gate electrode of the driving thin film transistor T1. The compensation source region may be connected to a first initialization drain region of the first initialization thin film transistor T4.

The compensation thin film transistor T3 may be turned on in accordance with the second scan signal Sn′ received through the second scan line SL2 and may electrically connect the driving gate electrode of the driving thin film transistor T1 and the driving drain region thereof to diode connect the driving thin film transistor T1.

A first initialization gate electrode of the first initialization thin film transistor T4 may be connected to the previous scan line SLp. A first initialization source region of the first initialization thin film transistor T4 may be connected to a second initialization source region of the second initialization thin film transistor T7 and to the first initialization voltage line VL1. The first initialization drain region of the first initialization thin film transistor T4 may be connected to the first electrode CE1 of the storage capacitor Cst, the compensation source region of the compensation thin film transistor T3, and the driving gate electrode of the driving thin film transistor T1. The first initialization thin film transistor T4 may be turned on in accordance with the previous scan signal Sn−1 received through the previous scan line SLp and may perform an initialization operation of initializing a voltage of the driving gate electrode of the driving thin film transistor T1 by transmitting the initialization voltage Vint to the driving gate electrode of the driving thin film transistor T1.

An operation control gate electrode of the operation control thin film transistor T5 may be connected to the light emission control line ECL, an operation control source region of the operation control thin film transistor T5 may be connected to the driving voltage line PL, and an operation control drain region of the operation control thin film transistor T5 may be connected to the driving source region of the driving thin film transistor T1 and to the switching drain region of the switching thin film transistor T2.

A light emission control gate electrode of the light emission control thin film transistor T6 may be connected to the light emission control line ECL, a light emission control source region of the light emission control thin film transistor T6 may be connected to the driving drain region of the driving thin film transistor T1 and to the compensation drain region of the compensation thin film transistor T3, and a light emission control drain region of the light emission control thin film transistor T6 may be electrically connected to a second initialization drain region of the second initialization thin film transistor T7 and to the pixel electrode of the light emission element LD.

The operation control thin film transistor T5 and the light emission control thin film transistor T6 may be simultaneously turned on in accordance with the light emission control signal En received through the light emission control line ECL, so that the driving voltage ELVDD may be transmitted to the light emission element LD to allow the driving current ILD to flow in the light emission element LD.

A second initialization gate electrode of the second initialization thin film transistor T7 may be connected to the next scan line SLn, the second initialization drain region of the second initialization thin film transistor T7 may be connected to the light emission control drain region of the light emission control thin film transistor T6 and to the pixel electrode of the light emission element LD, and the second initialization source region of the second initialization thin film transistor T7 may be connected to the second initialization voltage line VL2 to be provided with an anode initialization voltage Aint. The second initialization thin film transistor T7 may be turned on in accordance with the next scan signal Sn+1 received through the next scan line SLn and may initialize the pixel electrode of the light emission element LD.

In another embodiment, the second initialization thin film transistor T7 may be connected to the light emission control line ECL and driven in accordance with the light emission control signal En. The positions of the source regions and the drain regions may be changed depending on the type (p-type or n-type) of a transistor.

The storage capacitor Cst may include the first electrode CE1 and a second electrode CE2. The first electrode CE1 of the storage capacitor Cst may be connected to the driving gate electrode of the driving thin film transistor T1, and the second electrode CE2 of the storage capacitor Cst may be connected to the driving voltage line PL. In the storage capacitor Cst, electric charges corresponding to the difference between the voltage of the driving gate electrode of the driving thin film transistor T1 and the driving voltage ELVDD may be stored.

A boosting capacitor Cbs may include a first electrode CE1′ and a second electrode CE2′. The first electrode CE1′ of the boosting capacitor Cbs may be connected to the first electrode CE1 of the storage capacitor Cst, and the second electrode CE2′ of the boosting capacitor Cbs may be provided with the first scan signal Sn. The boosting capacitor Cbs may increase the voltage of a gate terminal of the driving thin film transistor T1 at a time when the supply of the first scan signal Sn is stopped, thereby compensating for a voltage drop of the gate terminal.

The specific operation of each pixel PX according to an embodiment may be as follows.

During an initialization period, in case that the previous scan signal Sn−1 is supplied through the previous scan line SLp, the first initialization thin film transistor T4 may be turned on in correspondence to the previous scan signal Sn−1, and the driving thin film transistor T1 may be initialized by the initialization voltage Vint supplied from the first initialization voltage line VL1.

During a data programming period, in case that the first scan signal Sn and the second scan signal Sn′ are supplied through the first scan line SL1 and the second scan line SL2, the switching thin film transistor T2 and the compensation thin film transistor T3 may be turned on in correspondence to the first scan signal Sn and the second scan signal Sn′. The driving thin film transistor T1 may be diode connected by the turned-on compensation thin film transistor T3, and may be biased in a forward direction.

A compensation voltage Dm+Vth (wherein Vth may be the value of (−)) reduced by a threshold voltage Vth of the driving thin film transistor T1 from the data signal Dm supplied from the data line DL may be applied to the driving gate electrode of the driving thin film transistor T1.

To both electrodes of the storage capacitor Cst, the driving voltage ELVDD and the compensation voltage Dm+Vth may be applied, and in the storage capacitor Cst, electric charges corresponding to the voltage difference between the both electrodes may be stored.

During a light emission period, the operation control thin film transistor T5 and the light emission control thin film transistor T6 may be turned on by the light emission control signal En supplied from the light emission control line ECL. The driving current ILD corresponding to the voltage difference between the voltage of the driving gate electrode of the driving thin film transistor T1 and the driving voltage ELVDD may be generated, and through the light emission control thin film transistor T6, the driving current ILD may be supplied to the light emission element LD.

In an embodiment, all of the thin film transistors T1 to T7 may be transistors each having a low-temperature polycrystalline silicon (LTPS) semiconductor layer, or transistors each using an oxide semiconductor as a semiconductor layer, or at least one of the thin film transistors T1 to T7 may be a transistor having a semiconductor layer, or a transistor using an oxide semiconductor as a semiconductor layer.

The driving thin film transistor T1 which directly affects the brightness of a display device may be configured to include a semiconductor layer made of polycrystalline silicon having high reliability, through which a high-resolution display device may be implemented.

Since an oxide semiconductor may have high carrier mobility and low leakage current, a voltage drop is not large even in case driving time is long. For example, since there may not be significant change in the color of an image due to a voltage drop even during low-frequency driving, low-frequency driving is possible.

Since the oxide semiconductor has the advantage of low leakage current as described above, at least one of the compensation thin film transistor T3, the first initialization thin film transistor T4, and the second initialization thin film transistor T7 which may be connected to the driving gate electrode of the driving thin film transistor T1 may be employed as an oxide semiconductor to prevent leakage current which may flow to the driving gate electrode and to reduce power consumption.

FIG. 5A is a schematic cross-sectional view illustrating a cross-section taken along line II-II′ of FIG. 3B. FIG. 5B is a schematic cross-sectional view illustrating a cross-section taken along line I-I′ of FIG. 3B.

Referring to FIG. 5A, the display layer DP may include a base layer 110, a circuit layer 120, a light emission element layer 130, and an encapsulation layer 140. The base layer 110 may be a member which provides a base surface on which the circuit layer 120 is disposed. The base layer 110 may be a rigid substrate, or a flexible substrate capable of bending, folding, rolling, and the like. The base layer 110 may be a glass substrate, a metal substrate, a polymer substrate, or the like. However, the embodiment is not limited thereto, and the base layer 110 may be an inorganic layer, an organic layer, or a composite material layer.

The base layer 110 may have a multi-layered structure. For example, the base layer 110 may include a first synthetic resin layer, an intermediate layer of a multi-layered or single-layered structure, and a second synthetic resin layer disposed on the intermediate layer. The intermediate layer may be referred to as a base barrier layer. The intermediate layer may include a silicon oxide (SiOx) layer and an amorphous silicon (amorphous silicon) layer disposed on the silicon oxide layer, but is not particularly limited thereto. For example, the intermediate layer may include at least one among a silicon oxide layer, a silicon nitride layer, a silicon oxynitride layer, and an amorphous silicon layer.

Each of the first and second synthetic resin layers may include a polyimide-based resin. Each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the disclosure “˜˜”-based resin means that a functional group of “˜˜” may be included.

The base layer 110 according to an embodiment may be divided into the first display region DA1, the second display region DA2, and the non-display region NDA. The second display region DA2 may include a second region SEA2, and a first region SEAL As described above, the second display region DA2 may be a region in which an image is displayed, and the non-display region NDA may be a region adjacent to the second display region DA2.

The circuit layer 120 may be disposed on the base layer 110. The circuit layer 120 may include an insulation layer, a semiconductor pattern, a conductive pattern, a signal line, and the like. The insulation layer, a semiconductor layer, and a conductive layer may be formed on the base layer 110 by coating, deposition, or the like, and thereafter, the insulation layer, the semiconductor layer, and the conductive layer may be selectively patterned through performing a photolithography process multiple times. Thereafter, the semiconductor pattern, the conductive pattern, and the signal line which may be included in the circuit layer 120 may be formed.

The circuit layer 120 may include insulation layers 10, 20, 30, 40, and 50, a pixel circuit, and a driving circuit. The base layer 110 may be divided into a pixel circuit region CAA and a driving circuit region CPA. The pixel circuit region CAA may be defined in the second display region DA2, and the driving circuit region CPA may be defined overlapping a portion of the second display region DA2 and the non-display region NDA. The pixel circuit region CAA and the driving circuit region CPA may be distinguished according to components disposed in a lower portion of the light emission elements LD1, LD2, and LD3, that is, the placement of the circuit layer 120.

In the pixel circuit region CAA, a pixel circuit constituting the pixels PX (see FIG. 1) may be disposed. FIG. 5A illustrates three pixel transistors TR1, TR2, and TR3 in the pixel circuit. The three pixel transistors TR1, TR2, and TR3 may be respectively connected to three light emission elements LD1, LD2, and LD3 distinct from each other.

For example, the three light emission elements LD1, LD2, and LD3 may include a first light emission element LD1, a second light emission element LD2, and a third light emission element LD3 respectively disposed in the first display region DA1, the second region SEA2, and the first region SEA1.

For example, the pixel transistors TR1, TR2, and TR3 may include a first pixel transistor TR1 disposed in the first display region DA1, and a second pixel transistor TR2 and a third pixel transistor TR3, each of which may be disposed in the first region SEA1.

In an embodiment, a first insulation layer 10 may be disposed on the base layer 110. On the first insulation layer 10, the pixel transistors TR1, TR2, and TR3 may be disposed.

The first insulation layer 10 may include a barrier layer and a buffer layer. The barrier layer and the buffer layer may each be an inorganic layer. However, this is only an example, and the first insulation layer 10 may be a single layer or may include more layers, or may include an organic layer, but is not limited to any one embodiment.

In case that the first insulation layer 10 includes a buffer layer, the first insulation layer 10 may prevent metal atoms or impurities from diffusing from the base layer 110 to the pixel transistors TR1, TR2, and TR3. The first insulation layer 10 may control the rate of providing heat during a crystallization process for forming the pixel transistors TR1, TR2, and TR3 to allow the pixel transistors TR1, TR2, and TR3 to be uniformly formed.

The pixel transistors TR1, TR2, and TR3 may each include a semiconductor pattern SP and a control electrode GE. The semiconductor pattern SP includes a semiconductor material such as silicon, a metal oxide, and the like.

The semiconductor pattern SP may include a channel AC, a source SE, and a drain DE. The channel AC, the source SE, and the drain DE may be portions separated on a plane. The channel AC may have low conductivity compared to the source SE, and the drain DE.

In an embodiment, the source SE, and the drain DE may include a reduced metal. The source SE, and the drain DE may respectively function as a source electrode and a drain electrode of the first pixel transistor TR1. However, this is only an example. The first pixel transistor TR1 may further include a separate source electrode and a separate drain electrode connected to the source SE, and the drain DE of the first pixel transistor TR1, and is not limited to any one embodiment.

The control electrode GE may be conductive. The control electrode GE may be spaced apart from the semiconductor pattern SP with a second insulation layer 20 interposed therebetween. The control electrode GE overlaps the channel AC of the semiconductor pattern SP on a plane. The second insulation layer 20 may be an inorganic layer, and may be single-layered or multi-layered.

On the pixel transistors TR1, TR2, and TR3, a third insulation layer 30, a fourth insulation layer 40 (or a first intermediate insulation layer), a fifth insulation layer 50 (or a second intermediate insulation layer), and a sixth insulation layer 60 (or a third intermediate insulation layer) may be laminated. The third to sixth insulation layers 30, 40, 50, and 60 may each include an inorganic layer or an organic layer and an inorganic layer which are laminated.

A first connection electrode CN1 may be disposed between the third insulation layer 30 and the fourth insulation layer 40. Multiple first connection electrodes CN1 may be provided, and may be respectively connected to the pixel transistors TR1, TR2, and TR3 through the third insulation layer 30 and the second insulation layer 20. In an embodiment, the first connection electrode CN1 is illustrated as being connected to the drain DE, but this is an example, and the first connection electrode CN1 may be connected to the source SE, but is not limited to any one embodiment.

A second connection electrode CN2 (or a first conductive pattern) may be disposed between the fourth insulation layer 40 and the fifth insulation layer 50. Multiple second connection electrodes CN2 may be provided, and may be connected to the first connection electrode CN1 through the fourth insulation layer 40. Any one among the second connection electrodes CN2 may be connected to the first light emission element LD1.

A third connection electrode CN3 (or a second conductive pattern) may be disposed between the fifth insulation layer 50 and the sixth insulation layer 60. Multiple third connection electrodes CN3 may be provided, and may be connected to the second connection electrode CN2 through the fifth insulation layer 50. The third connection electrode CN3 may be connected to the second light emission element LD2 and the third light emission element LD3.

The first connection electrode CN1, the second connection electrode CN2, and the third connection electrode CN3 may each independently include various materials such as a metal, a transparent conductive oxide, a conductive polymer, and the like. For example, the third connection electrode CN3 may include a transparent conductive oxide.

The first light emission element LD1 may be connected to the second connection electrode CN2 disposed in the first display region DM. The first light emission element LD1 directly contacts an upper surface of the second connection electrode CN2 through a first through-hole OP1 passing through the fifth insulation layer 50 and the sixth insulation layer 60. For the upper surface of the second connection electrode CN2 to which the first light emission element LD1 may be connected, the width of an upper surface exposed by the first through-hole OP1 may be defined as a first width WD1. The first width WD1 may be a value measured in the first direction DR1.

The second connection electrode CN2 to which the first light emission element LD1 is connected may be connected to the first connection electrode CN1 disposed in the first display region DA1.

The second connection electrode CN2 and the first connection electrode CN1 which may be connected to the first light emission element LD1 may be connected to the first pixel transistor TR1 disposed in the first display region DM. For example, the first light emission element LD1 and the first pixel transistor TR1 may be disposed in the same region.

The second light emission element LD2 may be connected to the third connection electrode CN3 overlapping the second region SEA2 and the first region SEA1. The second light emission element LD2 directly contacts an upper surface of the third connection electrode CN3 through a second through-hole OP2 passing through the sixth insulation layer 60. Of the upper surface of the third connection electrode CN3 to which the second light emission element LD2 may be connected, the width of an upper surface exposed by the second through-hole OP2 may be defined as a second width WD2. The second width WD2 may be a value measured in the first direction DR1.

The second light emission element LD2 may be connected to the third connection electrode CN3 disposed in the second region SEA2.

The third connection electrode CN3 to which the second light emission element LD2 is connected, may be connected to the second connection electrode CN2 disposed in the first region SEAL The second connection electrode CN2 may be connected to the second pixel transistor TR2 disposed in the first region SEA1.

The third connection electrode CN3 connected to the second light emission element LD2 may have a relatively large plane area compared to the second connection electrode CN2 connected to the first light emission element LD1 and the third connection electrode CNF3 connected to the third light emission element LD3.

The third connection electrode CN3 connected to the second light emission element LD2 may connect the second light emission element LD2 and the second pixel transistor TR2 which may be disposed in different regions.

The third light emission element LD3 may be connected to the third connection electrode CN3 disposed in the first region SEAL The third light emission element LD3 may contact (e.g., directly contact) the upper surface of the third connection electrode CN3 through the second through-hole OP2 passing through the sixth insulation layer 60. Of the upper surface of the third connection electrode CN3 to which the third light emission element LD3 may be connected, the width of an upper surface exposed by the second through-hole OP2 may be defined as a third width WD3. The third width WD3 may be a value measured in the first direction DR1.

The third connection electrode CN3, the second connection electrode CN2, and the first connection electrode CN2 which may be connected to the third light emission element LD3 may be connected to the third pixel transistor TR3 disposed in the first region SEA1. For example, the third light emission element LD3 and the third pixel transistor TR3 may be disposed in the same region.

The light emission element layer 130 may be disposed on the circuit layer 120. The light emission element layer 130 may include a light emission element. For example, the light emission element layer 130 may include an organic light emission material, an inorganic light emission material, an organic-inorganic light emission material, a quantum dot, a quantum rod, a micro-LED, or a nano-LED.

The light emission elements LD1, LD2, and LD3 may be disposed on the sixth insulation layer 60, and may be electrically connected to corresponding pixel transistors TR1, TR2, and TR3 through the connection electrodes CN1, CN2, and CN3. The encapsulation layer 140 may be disposed on the light emission element layer 130. The encapsulation layer 140 may protect the light emission element layer 130 from foreign materials such as moisture, oxygen, and dust particles.

The encapsulation layer 140 may be disposed on the light emission element layer 130. The encapsulation layer 140 may include an inorganic layer 141, an organic layer 142, and an inorganic layer 143 sequentially stacked, but layers constituting the encapsulation layer 140 are not limited thereto.

The inorganic layers 141 and 143 may protect the light emission element layer 130 from moisture and oxygen, and the organic layer 142 may protect the light emission element layer 130 from foreign materials such as dust particles. The inorganic layers 141 and 143 may include a silicon nitride layer, a silicon oxynitride layer, a silicon oxide layer, a titanium oxide layer, an aluminum oxide layer, or the like. The organic layer 142 may include an acrylic organic layer, but is not limited thereto.

As described above, the light emission elements LD1, LD2, and LD3 may include the first light emission element LD1 disposed in the first display region DA1, the second light emission element LD2 disposed in the second region SEA2, and the third light emission element LD3 disposed in the first region SEA1. Multiple first to third light emission elements LD1, LD2, and LD3 may each be provided, but may each be described as a single light emission element in embodiments.

The first light emission element LD1 may be disposed in the first display region DA1, the same region as the first pixel transistor TR1, to which the first light emission element LD1 may be connected. The first light emission element LD1 overlaps, on a plane, the first pixel transistor TR1, to which the first light emission element LD1 may be connected. The first display region DA1 may be defined in the pixel circuit region CAA.

The first light emitting element LD1 may include a first electrode AE1, a second electrode CE, and a first light emission layer EL1. The first electrode AE1 may be disposed on the sixth insulation layer 60, and may be connected to the second connection electrode CN2 through the sixth insulation layer 60.

The first electrode AE1 may be provided with a reflective layer formed of Ag, Mg, Al, Pt, Pd, Au, Ni, Nd, Ir, Cr, or a compound thereof, and a transparent or translucent electrode layer may be formed on the reflective layer. The transparent or translucent electrode layer may be provided with at least one selected from the group consisting of indium tin oxide (ITO), indium zinc oxide (IZO), indium gallium zinc oxide (IGZO), zinc oxide (ZnO), or indium oxide (In2O3), and aluminum-doped zinc oxide (AZO). For example, the first electrode AE1 may be provided as ITO/Ag/ITO.

A pixel definition film PDL may include an opening which exposes at least a portion of the first electrode AE1. The pixel definition film PDL may be disposed on the sixth insulation layer 60. In the embodiment, the pixel definition film PDL may have properties of absorbing light, and for example, the pixel definition film PDL may have a black color. The pixel definition PDP may include a black coloring agent. For example, the black coloring agent may include a black dye or a black pigment, or may include a metal such as carbon black or chromium or an oxide thereof. The pixel definition film PDL may include an organic matter and/or an inorganic matter.

The first light emission layer EL1 may be disposed in the opening defined in the pixel definition film PDL. The first light emission layer EL1 may include an organic light emission material and/or an inorganic light emission material. The first light emission element LD1 may generate light by exciting the first light emission layer EL1 according to a potential difference between the first electrode AE1 and the second electrode CE.

The second electrode CE may be disposed on the pixel definition film PDL. The second electrode CE may be provided in the shape of a single body which covers light emission element layers. The second electrode CE may be formed on a front surface of the second display region DA2.

Although not illustrated, a hole control layer may be disposed between the first electrode AE1 and the first light emission layer EL1. The hole control layer may include a hole transport layer, and may further include a hole injection layer. An electron control layer may be disposed between the first light emission layer EL1 and the second electrode CE. The electron control layer may include an electron transport layer, and may further include an electron injection layer. The hole control layer and the electron control layer may be commonly formed in the pixels PX (see FIG. 1) using an open mask.

The second light emission element LD2 may be disposed in the second region SEA2 in the second display region DA2. In an embodiment, the second region SEA2 may be a region in which light emission elements not overlapping pixel transistors, to which the light emission elements are connected, may be disposed in the second display region DA2. The second region SEA2 may be a region overlapping the driving circuit region CPA, and particularly, may be a region overlapping the driving part GDC (see FIG. 3B).

In the driving circuit region CPA, circuit components other than a pixel circuit unit, for example, the driving part GDC (see FIG. 3B), the initialization voltage line Vint, the first initialization voltage line VL1, and a shielding line Vis, and the like may be disposed.

The initialization voltage line Vint may be disposed in the second display region DA2, and may be disposed overlapping the second region SEA2. A conductive line Ci disposed on the fourth insulation layer 40 may be connected to the initialization voltage line Vint through the fourth insulation layer 40, and may be extended toward the pixel circuit region CAA to provide an initialization voltage to the pixel driving circuit.

The shielding line Vis may be connected to the initialization voltage line Vint. The shielding line Vis may electrically shield the second light emission element LD2. A problem in which noise is generated in the second light emission element LD2 may be prevented by driving transistors TRP1 and TRP2 of the shielding line Vis.

The driving part GDC (see FIG. 3B) and the initialization voltage line Vint may be disposed in a region of the driving circuit region CPA overlapping the second display region DA2. FIG. 5A illustrates some driving transistors TRP1 and TRP2 of the driving part GDC.

The driving transistor TRP1 may include the semiconductor pattern SP, a control electrode E1, an input electrode E2, and an output electrode E3. The driving transistors TRP1 and TRP2 may be formed through the same process as the process of forming the pixel transistors TR1, TR2, and TR3. The driving transistors TRP1 and TRP2 may be disposed not overlapping the pixel transistors TR1, TR2, and TR3 on a plane.

The second light emission element LD2 and the second pixel transistor TR2 may be disposed in different regions. The second light emission element LD2 may not overlap the second pixel transistor TR2 on a plane, and may overlap the driving transistors TRP1 and TRP2, which constitute the driving part GDC, on a plane. Accordingly, the third connection electrode CN3 may be extended from the first region SEA1 to the second region SEA2 to connect the second light emission element LD2 and the second pixel transistor TR2.

The third light emission element LD3 may be disposed in the first region SEAL The first region SEA1 may be a region defined between the first display region DA1 and the second region SEA2, and may be a region overlapping a portion of the pixel circuit region CAA.

Each of the second and third light emission elements LD2 and LD3 may be provided in the same structure as the structure of the first light emission element LD1. For example, the second light emission element LD2 may include a first electrode AE2, a second light emission layer EL2, and a common electrode CE, and the third light emission element LD3 (see FIG. 5A) may include a first electrode AE3, a third light emission layer EL3, and a common electrode CE. However, this is only an example, and the first to third light emission elements LD1, LD2, and LD3 may have structures different from each other, and are not limited to any one embodiment.

A power voltage pattern VSS may be connected to the first initialization voltage line VL1 to receive a first power voltage.

The display panel DP according to an embodiment may include multiple dams P0 and P1, and a crack dam CRD. The dams P0 and P1 may be disposed along the edge of a display region DDA. The dams P0 and P1 may prevent the organic layer 142 from overflowing. The dams P0 and P1 may include a first dam P0 and a second dam P1.

Between the dams P0 and P1, the first dam P0 may be relatively more adjacent to the second display region DA2. The first dam P0 may overlap the first initialization voltage line VL1. The first dam P0 may include a first layer P01, a second layer P02, and a third layer P03. The first layer P01, the second layer P02, and the third layer P03 may be each formed of an insulation material. In an embodiment, the first layer P01 may be formed of the same material as the material of which the fifth insulation layer 50 is formed, and the second layer P02 and the third layer P03 may be formed of the same material as the material of which the sixth insulation layer 60 and/or a pixel definition film PDL are formed.

Between the dams P0 and P1, the second dam P1 may be relatively more spaced apart from the second display region DA2. In an embodiment, the second dam P1 may include a first layer P11, a second layer P12, a third layer P13, and a fourth layer P14. For example, the first layer P11 may be formed of the same material as the material of which the fourth insulation layer 40 is formed, the second layer P12 may be formed of the same material as the material of which the fifth insulation layer 50 is formed, and the third layer P13 and the fourth layer P14 may be formed of the same material as the material of which the sixth insulation layer 60 and/or a pixel definition film PDL are formed. The first dam P0 and the second dam P1 may have a same layered structure, and an additional dam other than the first dam P0 and the second dam P1 may be further disposed in the non-display region NDA, but embodiments are not limited thereto.

The crack dam CRD may be disposed in the non-display region NDA, and may be disposed at ends of the second insulation layer 20 and the third insulation layer 30. The crack dam CRD may include a dam portion DM and a filling portion FL. The dam DM may include insulation patterns disposed spaced apart in a direction toward an edge of the display panel DP from the display region DDA. The insulation patterns may be formed of the same material as the material of which the second insulation layer 20 and the third insulation layer 30 are formed, and may be simultaneously formed.

The filling portion FL may include an organic matter. The filling portion FL may be formed of a material which has a relatively high ductility compared to that of the dam portion DM. The filling portion FL may cover the dam portion DM and fill between the insulation patterns.

FIG. 5B is a schematic cross-sectional view of the display device DD according to an embodiment. FIG. 5B illustrates a portion of the first display region DA1 and a portion of the second region SEA2. The same reference numerals are given to the same components as those described with reference to FIG. 1 to FIG. 5A, and redundant descriptions thereof may be omitted.

Referring to FIG. 5B, the display device DD according to an embodiment may include a display panel DP-1, a sensor layer 200, and a refection prevention layer 300.

The display panel DP-1 of an embodiment may include a transistor including an oxide semiconductor O-TFT (hereinafter, an oxide thin film transistor) and a transistor including a polysilicon semiconductor P-TFT (hereinafter, silicon thin film transistor).

A first back metal layer BMLa may be disposed in a lower portion of the silicon thin film transistor S-TFT, and a second back metal layer BMLb may be disposed in a lower portion of the oxide thin film transistor O-TFT. The first black metal layer BMLa and the second back metal layer BMLb may be disposed to overlap the lower portion of each of the silicon thin film transistor S-TFT and the oxide thin film transistor O-TFT to protect the silicon thin film transistor S-TFT and the oxide thin film transistor O-TFT. The first black metal layer BMLa and the second back metal layer BMLb may block external light from reaching the silicon thin film transistor S-TFT and the oxide thin film transistor O-TFT.

The first back metal layer BMLa may be disposed corresponding to at least some regions of a circuit of the pixel PX (see FIG. 3A). In an embodiment, the first back metal layer BMLa may be disposed to overlap the driving thin film transistor T1 (see FIG. 4) provided as the silicon thin film transistor S-TFT.

The first back metal layer BMLa may be disposed between the base layer 110 and the first insulation layer 10. In an embodiment, the first back metal layer BMLa may be disposed on the base layer 110 in which an organic film and an inorganic film may be alternately laminated, and an inorganic barrier layer may further be disposed between the first back metal layer BMLa and the first insulation layer 10. The first back metal layer BMLa may be connected to an electrode or a line to receive a constant voltage or a signal therefrom. In another embodiment, the first back metal layer BMLa may be provided in an isolated form from another electrode or another line.

The second back metal layer BMLb may be disposed corresponding to the lower portion of the oxide thin film transistor O-TFT. The second back metal layer BMLb may be disposed between the second insulation layer 20 and the third insulation layer 30. The second back metal layer BMLb may be disposed on the same layer as the layer on which the second capacitor electrode CE2 of the storage capacitor Cst is disposed. The second back metal layer BML2 may be connected to a contact electrode BML2-C to receive a constant voltage or a signal. The contact electrode BML2-C may be disposed on the same layer as the layer on which a second gate GT2 of the oxide thin film transistor O-TFT is disposed.

The first back metal layer BMLa and the second back metal layer BMLb may each include a reflective metal. For example, the first back metal layer BMLa and the second back metal layer BMLb may each include silver (Ag), an alloy containing silver, molybdenum (Mo), an alloy containing molybdenum, aluminum (A1), an alloy containing aluminum, an aluminum nitride (AlN), tungsten (W), a tungsten nitride (WN), copper (Cu), p+ doped amorphous silicon, and the like. The first back metal layer BMLa and the second back metal layer BMLb may include the same material, or may include different metals.

A first semiconductor pattern may be disposed on the first insulation layer 10. The first semiconductor pattern may include a silicon semiconductor. For example, the silicon semiconductor may include amorphous silicon, polycrystalline silicon, and the like. For example, the first semiconductor pattern may include low-temperature polysilicon.

FIG. 5B only illustrates a portion of the first semiconductor pattern disposed on the first insulation layer 10, and the first semiconductor pattern may further be disposed in another region. The first semiconductor pattern may be arranged across pixels according to a specific rule. The first semiconductor pattern may have different electrical properties depending on whether or not the first semiconductor pattern is doped. The first semiconductor pattern may include a first region having a high conductivity rate and a second region having a low conductivity rate. The first region may be doped with an N-type dopant or a P-type dopant. A P-type transistor may include a doped region which has been doped with the P-type dopant, and an N-type transistor may include a doped region which has been doped with the N-type dopant. The second region may be a non-doped region, or a region doped to a concentration lower than that of the first region.

A conductivity of the first region may be greater than a conductivity of the second region, and the first region may substantially serve as an electrode or a signal line. The second region may substantially correspond to an active region (or a channel) of a transistor. In other words, a portion of a semiconductor pattern may be an active region of a transistor, another portion thereof may be a source or a drain of the transistor, and the other portion thereof may be a connection electrode or a connection signal line.

A source region SE1, an active region AC1, and a drain region DE1 of the silicon thin film transistor S-TFT may be formed from the first semiconductor pattern. The source region SE1 and the drain region DE1 may be extended in opposite directions from the active region AC1 on a cross section.

The first insulation layer 10 may be a layer disposed on the base layer 110, and the third insulation layer 30 may be a layer on which the first connection electrode CN1 is disposed. In case that comparing the display panel DP-1 illustrated in FIG. 5B with the display panel DP illustrated in FIG. 5A, multiple insulation layers may be disposed between the first insulation layer 10 and the third insulation layer 30. For example, the second insulation layer 20 disposed between the first insulation layer 10 and the third insulation layer 30 may include a 2-1 insulation layer to a 2-4 insulation layer 21, 22, 23, and 24.

The 2-1 insulation layer 21 may be disposed on the first insulation layer 10. The 2-1 insulation layer 21 commonly overlaps pixels, and may cover the first semiconductor pattern. The 2-1 insulation layer 21 may be an inorganic layer and/or an organic layer, and may have a single-layered or multi-layered structure. The 2-1 insulation layer 21 may include at least one of an aluminum oxide, a titanium oxide, a silicon oxide, a silicon nitride, a silicon oxynitride, a zirconium oxide, or a hafnium oxide. In an embodiment, the first insulation layer 10 may be a single-layered silicon oxide layer. Not only the 2-1 insulation layer 21 but also an insulation layer of the circuit layer 120 to be described later may be an inorganic layer and/or an organic layer, and may have a single-layered or multi-layered structure. The inorganic layer may include at least one of the above-described materials, but the embodiments are not limited thereto.

A gate GT1 of the silicon thin film transistor S-TFT may be disposed on the 2-1 insulation layer 21. The gate GT1 may be a portion of a metal pattern. The gate GT1 may overlap the active region AC1. In a process of doping the first semiconductor pattern, the gate GT1 may function as a mask. The gate GT1 may include titanium (Ti), silver (Ag), an alloy containing silver, molybdenum (Mo), an alloy containing molybdenum, aluminum (A1), an alloy containing aluminum, an aluminum nitride (AlN), tungsten (W), a tungsten nitride (WN), copper (Cu), an indium tin oxide (ITO), an indium zinc oxide (IZO), and the like, but is not particularly limited thereto.

The 2-2 insulation layer 22 may be disposed on the 2-1 insulation layer 21, and may cover the gate GT1. The 2-2 insulation layer 22 may be an inorganic layer and/or an organic layer, and may have a single-layered or multi-layered structure. The 2-2 insulation layer 22 may include at least one of a silicon oxide, a silicon nitride, or a silicon oxynitride. In an embodiment, the 2-2 insulation layer 22 may have a multi-layered structure including a silicon oxide layer and a silicon nitride layer.

The 2-3 insulation layer 23 may be disposed on the 2-2 insulation layer 22. The 2-3 insulation layer 23 may have a single-layered or multi-layered structure. For example, the 2-3 insulation layer 23 may have a multi-layered structure including a silicon oxide layer and a silicon nitride layer. An upper electrode UE may be disposed between the 2-2 insulation layer 22 and the 2-3 insulation layer 23. The upper electrode UE may overlap at least a portion of the gate GT1 of the silicon thin film transistor S-TFT disposed in a lower portion thereof. The upper electrode UE may be a portion of a metal pattern or a portion of a doped semiconductor pattern. A portion of the gate GT1 and the upper electrode UE overlapping the same may form the storage capacitor Cst (see FIG. 4). For example, the portion of the gate GT1 may be the first capacitor electrode CE1 (see FIG. 4), and the upper electrode UE may be the second capacitor electrode CE2. However, the upper electrode UE may be omitted.

A second semiconductor pattern may be disposed on the 2-3 insulation layer 23. The second semiconductor pattern may include an oxide semiconductor. A source region SE2, an active region AC2, and a drain region DE2 of the oxide thin film transistor O-TFT may be formed from the second semiconductor pattern. The source region SE2 and the drain region DE2 may be extended in opposite directions from the active region AC2 on a cross section.

The 2-4 insulation layer 24 may be disposed on the 2-3 insulation layer 23. The 2-4 insulation layer 24 commonly overlaps pixels, and may cover the second semiconductor pattern. The 2-4 insulation layer 24 may include at least one of an aluminum oxide, a titanium oxide, a silicon oxide, a silicon nitride, a silicon oxynitride, a zirconium oxide, or a hafnium oxide.

The gate GT2 of the oxide thin film transistor O-TFT may be disposed on the 2-4 insulation layer 24. The gate GT2 may be a portion of a metal pattern. The gate GT2 may overlap the active region AC2. In a process of doping the second semiconductor pattern, the gate GT2 may function as a mask.

The third insulation layer 30 may be disposed on the 2-4 insulation layer 24, and may cover the gate GT2. The third insulation layer 30 may be an inorganic layer and/or an organic layer, and may have a single-layered or multi-layered structure.

The first connection electrode CN1 may be disposed on the third insulation layer 30. The first connection electrode CN1 may be connected to the drain region DE1 of the silicon transistor S-TFT through a contact hole passing through the first insulation layer 10 and the second insulation layer 20.

The second connection electrode CN2 may be disposed on the fourth insulation layer 40. The second connection electrode CN2 may be connected to the first connection electrode CN1 through a contact hole passing through the fourth insulation layer 40. The fifth insulation layer 50 may be disposed on the fourth insulation layer 40, and may cover the second connection electrode CN2.

The sixth insulation layer 60 may be disposed on the fifth insulation layer 50.

In the first display region DA1, the first electrode AE1 of the first light emission element LD1 may be connected to the second connection electrode CN2 through the first through-hole OP1. As described above, the first through-hole OP1 passes through the fifth insulation layer 50 and the sixth insulation layer 60.

In the second region SEA2, the third connection electrode CN3 may be disposed on the fifth insulation layer 50. The third connection electrode CN3 may not be disposed in the first display region DA1, and may be disposed in the second region SEA2.

As illustrated in FIG. 5A, the third connection electrode CN3 may be connected to the second connection electrode CN2 through a contact hole passing through the fifth insulation layer 50.

The fourth insulation layer 40, the fifth insulation layer 50, and the sixth insulation layer 60 may each be an organic layer. For example, the fourth insulation layer 40, the fifth insulation layer 50, and the sixth insulation layer 60 may each include a general purpose polymer such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

A scan driving circuit disposed in the second area SEA2 may also be formed in the same manner as a pixel driving circuit of the first display region DA1. The scan driving circuit may include a driving transistor including a polysilicon semiconductor S-TFTP (hereinafter, a silicon driving transistor) and a driving transistor including an oxide semiconductor O-TFTP (hereinafter, an oxide driving transistor). The silicon driving transistor S-TFTP and the oxide driving transistor O-TFTP may respectively have the same structure as the structure of the silicon thin film transistor S-TFT and the structure of the oxide thin film transistor O-TFT, and hereinafter, redundant descriptions will be omitted.

As described above, the light emission element layer 130 may be disposed on the circuit layer 120, and the encapsulation layer 140 may be disposed on the light emission element layer 130.

The sensor layer 200 may be disposed on the display panel DP-1. The sensor layer 200 may be referred to as a sensor, an input sensing layer, or an input sensing panel. The sensor layer 200 may include a base layer 210, a first conductive layer 220, a sensing insulation layer 230, a second conductive layer 240.

The base layer 210 may be directly disposed on the display panel DP-1. The base layer 210 may be an inorganic layer including at least one of silicon nitride, silicon oxynitride, or silicon oxide. Alternatively, the base layer 210 may be an organic layer including an epoxy resin, an acrylic resin, or an imide-based resin. The base layer 210 may have a single-layered structure, or a multi-layered structure in which layers are laminated along the third direction DR3.

Each of the first conductive layer 220 and the second conductive layer 240 may have a single-layered structure, or a multi-layered structure in which layers are laminated along the third direction DR3.

A conductive layer of a single-layered structure may include a metal layer or a transparent conductive layer. The metal layer may include molybdenum, silver, titanium, copper, aluminum, or an alloy thereof. The transparent conductive layer may include a transparent conductive oxide such as an indium tin oxide (ITO), an indium zinc oxide (IZO), a zinc oxide (ZnO), an indium tin zinc oxide (ITZO), or the like. The transparent conductive layer may include a conductive polymer such as PEDOT, a metal nanowire, graphene, and the like.

A conductive layer of a multi-layered structure may include metal layers. The metal layers may have, for example, a three-layered structure of titanium/aluminum/titanium. The conductive layer of a multi-layered structure may include at least one metal layer and at least one transparent conductive layer.

The sensing insulation layer 230 may be disposed between the first conductive layer 220 and the second conductive layer 240. The sensing insulation layer 230 may include an inorganic film. The inorganic film may include at least one of an aluminum oxide, a titanium oxide, a silicon oxide, a silicon nitride, a silicon oxynitride, a zirconium oxide, or a hafnium oxide.

Alternatively, the sensing insulation layer 230 may include an organic film. The organic film may include at least any one among an acrylic resin, a methacryl-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

The refection prevention layer 300 may be disposed on the sensor layer 200. The refection prevention layer 300 may include a partition layer 310, a color filter 323, and a planarization layer 330.

A material constituting the partition layer 310 may be light absorbing and is not particularly limited. The partition layer 310 may be a layer having a black color, and in an embodiment, the partition layer 310 may include a black coloring agent. The black coloring agent may include a black dye and a black pigment. The black coloring agent may include a metal such as carbon black or chromium, or an oxide thereof.

The partition layer 310 may cover the second conductive layer 240 of the sensor layer 200. The partition layer 310 may prevent external light reflection by the second conductive layer 240. Multiple openings 310-OP1 and 310-OP2 may be defined in the partition layer 310. A first opening 310-OP1 may overlap the first electrode AE1 of the first light emission element LD1, and a second opening 310-OP2 may overlap the first electrode AE2 of the second light emission element LD2.

The color filter 323 may be disposed overlapping the light emission elements LD1 and LD2, the first electrodes AE1 and AE2. The planarization layer 330 may over the partition layer 310 and the color filter 323. The planarization layer 330 may include an organic substance, and a flat surface may be provided on an upper surface of the planarization layer 330. In an embodiment, the planarization layer 330 may be omitted.

In an embodiment, the sensor layer 200 and the refection prevention layer 300 are illustrated as being disposed in both the first display region DA1 and the second region SEA2. However, this is only an example. In the display device DD according to an embodiment, the sensor layer 200 and the refection prevention layer 300 may be omitted in the second region SEA2, and are not limited to any one embodiment.

FIG. 6A is an enlarged schematic plan view of region A1 illustrated in FIG. 3B. FIG. 6B and FIG. 6C are each enlarged schematic plan views of region A3 illustrated in FIG. 6A. FIG. 6B shows a light emission element and a pixel driving circuit in region A3, and FIG. 6C shows a driver in region A3.

Although not separately illustrated, hereinafter, in the specification, the second to fourth corner regions DA2_C2 to DA2_C4 may have the same pixel configuration, pixel placement, driver shape, and emission region placement, which are the same as those of the first corner region DA2_C1 to be described later. The second edge region DA2_E2 may have the same pixel configuration, pixel placement, driver shape, and emission region placement, which are the same as those of the first edge region DA2_E1 to be described later. For example, the first corner region DA2_C1 represents the corner regions DA2_C1 to DA2_C4, and the first edge region DA2_E1 represents the second edge region DA2_E2.

In each of the first corner region DA2_C1 and the first display region DA1, three types of pixels may be disposed. The three types of pixels generating light of different colors may be defined as a first color pixel, a second color pixel, and a third color pixel. Each of the three types of pixels may include a driving circuit and a light emission element.

FIG. 6A illustrates light emission regions L-R, L-G, and L-B of light emission elements. A first light emission region L-R may be a light emission region of the first color pixel, a second light emission region L-G may be a light emission region of the second color pixel, and a third light emission region L-B may be a light emission region of the third color pixel. As an example, a pixel driving circuit DC and a light emission element ED (see FIG. 5A) disposed in the first light emission region L-R may constitute one pixel PX.

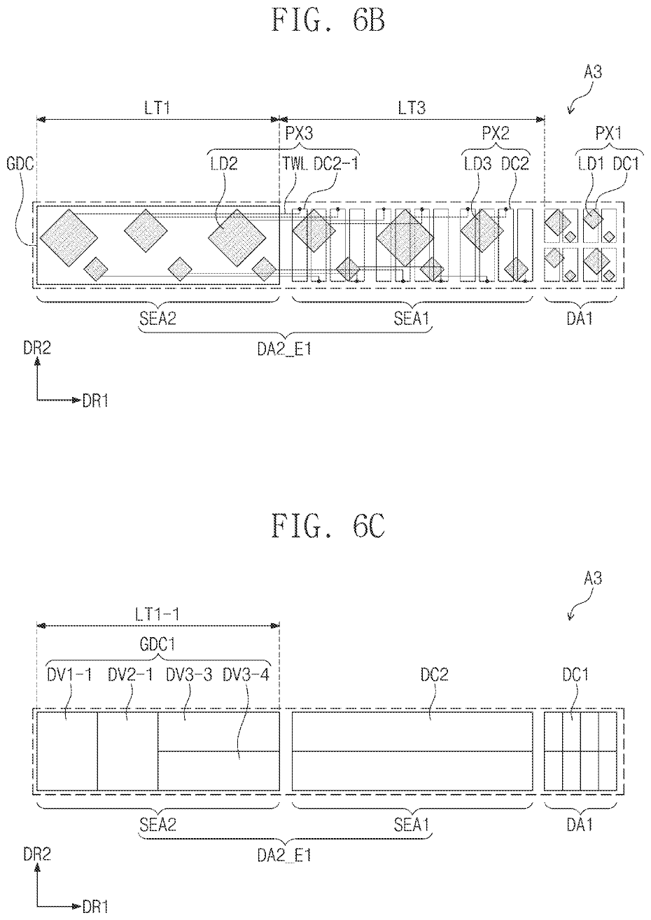

In FIG. 6A and FIG. 6B, the pixels PX1, PX2, and PX3 will be described, and in FIG. 6C and FIG. 7, the driving part GDC will be described. In FIG. 6B, the first pixel PX1 may include a first pixel driving circuit DC1 disposed in the first display region DA1 and the first light emission element LD1 connected to the first pixel driving circuit DC1. Here, the first light emission element LD1 may correspond to the first light emission region L-R of the first display region DA1. The second pixel PX2 may include a second pixel driving circuit DC2 disposed in the first region SEA1 of the second display region DA2 (see FIG. 2) and the third light emission element LD3 connected to the second pixel driving circuit DC2. The third pixel PX3 may include the second light emission element LD2 disposed in the second region SEA2 of the second display region DA2 (see FIG. 2), a second pixel driving circuit DC2-1 disposed in the first region SEA1, and a connection line TWL connecting the second light emission element LD2 and the second pixel driving circuit DC2-1. The connection line TWL may correspond to the third connection electrode CN3 (see FIG. 5A) connected to the second light emission element LD2 among the above-described connection electrodes. The connection line TWL may include various materials such as a metal, a transparent conductive oxide, a conductive polymer, and the like, and is not limited to any one embodiment.

Referring to FIG. 6A and FIG. 6B, the first display region DA1 of the display panel DP includes first unit regions UA1. The first unit regions UA1 may have the same placement of light emission regions as each other. The first unit regions UA1 may include the first light emission region L-R, the second light emission region L-G, and the third light emission region L-B. In an embodiment, the first unit regions UA1 may each include one first light emission region L-R, two second light emission regions L-G, and one third light emission region L-B. The first light emission region L-R and the third light emission region L-B may be disposed in a row in the second direction DR2, and the two second light emission regions L-G may be disposed in a row in the second direction DR2. The placement order and placement shape of the first to third light emission regions L-R, L-G, and L-B in the first unit region UA1 may be variously changed. For example, the first light emission region L-R and the third light emission region L-B may be disposed in a row in the first direction DR1, and the two second light emission regions L-G may be disposed in a row in the first direction DR1. As another example, the two second light emission regions L-G may face each other in a diagonal direction between the first direction DR1 and the second direction DR2, and the first light emission region L-R and the third light emission region L-B may be disposed to face each other in the diagonal direction.

In an embodiment, one of the two second light emission regions L-G may be defined as a fourth light emission region distinct from the second light emission region L-G. For example, the second light emission region L-G and the fourth light emission region may have different planar shapes. The number and type of light emission regions included in the first unit regions UA1 are not particularly limited.

In an embodiment, the first light emission region L-R may be a first color light emission region and may generate red light. Each of the two second light emission regions L-G may be a second color light emission region and may generate green light. The third light emission region L-B may be a third color light emission region and may generate blue light. The red light, the green light, and the blue light may be changed to other three primary color light.

The first edge region DA2_E1 may include the first region SEA1 and the second region SEA2. The first region SEA1 may be adjacent to the first display region DA1, and the second region SEA2 may be adjacent to the first region SEA1 and the non-display region NDA. The second region SEA2 overlaps the driving part GDC on a plane.

The first edge region DA2_E1 may include second unit regions UA2. The second unit regions UA2 may have the same placement of light emission regions as each other. The second unit regions UA2 may include the first light emission region L-R, the second light emission region L-G, and the third light emission region L-B. In an embodiment, each of the second unit regions UA2 may have the same placement of light emission regions as that of each of the first unit regions UA1.

The first region SEA1 may include the second pixel driving circuit DC2 corresponding to the first light emission region L-R, the second light emission region L-G, and the third light emission region L-B, but the second region SEA2 may not include the second pixel driving circuit DC2 corresponding to the first light emission region L-R, the second light emission region L-G, and the third light emission region L-B.

Since the first light emission region L-R, the second light emission region L-G, and the third light emission region L-B in the second region SEA2 overlap the driving part GDC on a plane, the second pixel driving circuit DC2 corresponding to the first light emission region L-R, the second light emission region L-G, and the third light emission region L-B in the second region SEA2 may be disposed in the first region SEA1.

In other words, in the first region SEA1, the second pixel driving circuits DC2 corresponding to the first light emission region L-R, the second light emission region L-G, and the third light emission region L-B in the first region SEA1, and the second pixel driving circuits DC2 corresponding to the first light emission region L-R, the second light emission region L-G, and the third light emission region L-B in the second region SEA2 may be disposed.

Light emission elements (not shown) corresponding to the first light emission region L-R, the second light emission region L-G, and the third light emission region L-B of the second region SEA2 may be electrically connected a corresponding second pixel driving circuit DC2 disposed in the first region SEA1.

The second unit region UA2 may be an area greater than the area of the first unit region UA1. For example, the first light emission region L-R in the second unit region UA2 may have an area greater than the area of the first light emission region L-R in the first unit region UA1. The second light emission region L-G in the second unit region UA2 may have an area greater than the area of the second light emission region L-G in the first unit region UA1. The third light emission region L-B in the second unit region UA2 may have an area greater than the area of the third light emission region L-R in the first unit region UA1.

For example, the area of each of the light emission regions L-R, L-G, and L-B of the first display region DA1 may be less than the area of each of the light emission regions L-R, L-G, and L-B of the first edge region DA2_E1. In case that light emission areas of corresponding light emission elements are different and the same driving voltage may be applied to the corresponding light emission elements, the luminance ratio of the corresponding light emission elements depends on the light emission area ratio.

Since the second unit region UA2 has an area greater than the area of the first unit region UA1, the first display region DA1 may have more light emission regions per unit area than the first edge region DA2_E1. The unit area may be an area greater than the area of the second unit region UA2, and may be set to an area two times or three times the area of the second unit region UA2.

Since the first edge region DA2_E1 has fewer light emission regions per unit area than the first display region DA1, in case that the same light emission region and the same driving condition are met, the luminance per unit area of the first edge region DA2_E1 may be lower than that of the first display region DA1. The same light emission area means that the areas of corresponding light emission regions of the first unit area UA1 and the second unit area UA2 may be the same. The same driving condition means that the same driving voltage may be applied to a light emission element.

According to an embodiment, in order to compensate for the luminance difference between the first edge region DA2_E1 and the first display region DA1, each of the first, second, and third light emission regions L-R, L-G, and L-B of the first edge region DA2_E1 may have a greater area than a corresponding light emission region among the first, second, and third light emission regions L-R, L-G, and L-B of the first display region DA1. In case that light emission areas of corresponding light emission elements are different and the same driving voltage is applied to the corresponding light emission elements, the luminance ratio of the corresponding light emission elements depends on the light emission area ratio.

In an embodiment, the first light emission region L-R of the first edge region DA2_E1 may have an area four times the area of the first light emission region L-R of the first display region DA1, the second light emission region L-G of the first edge region DA2_E1 may have an area four times the area of the second light emission region L-G of the first display region DA1, and the third light emission region L-B of the first edge region DA2_E1 may have an area four times the area of the third light emission region L-B of the first display region DA1. As a result, the first display region DA1 and the first edge region DA2_E1 may have the same area of a corresponding light emission region per unit area.

The lifespan of a light emission element may be determined depending on initial luminance and an acceleration coefficient. The acceleration coefficient may be affected by temperature, element properties, and material properties. In the first edge region DA2_E1, the area of a light emission region may be increased so as to increase the area of the entire light emission regions per unit area to correspond to the area of a light emission region per unit area of the first display region DA1. As the light emission luminance per unit area of the first edge region DA2_E1 increases, the initial luminance of a light emission region of the first edge region DA2_E1 may be lowered, so that the life expectancy of a light emission element of the first edge region DA2_E1 may be the same as that of a light emission element of the first display region DA1.

FIG. 6B shows the first pixel PX1 disposed in the first display region DA1 and the second pixel PX2 and the third pixel PX3 disposed in the first edge region DA2_E1, and FIG. 6C shows the first pixel driving circuit DC1, the second pixel driving circuit DC2, and the first driving part GDC1 disposed in the first display region DA1 and the first edge region DA2_E1.

Referring to FIG. 6C, the first driving part GDC1 may be disposed in the second region SEA2 of the first edge region DA2_E1. In the first region SEA1, the second pixel driving circuit DC2 may be disposed. In the first display region DA1, the first pixel driving circuit DC1 may be disposed.

The first driving part GDC1 may include a first driver DV1-1, a second driver DV2-1, and third drivers DV3-3 and DV3-4. The first driver DV1-1 and the second driver DV2-1 may correspond to a light emission driver. The third drivers DV3-3 and DV3-4 may correspond to scan drivers which send and receive signals with each of the first driver DV1-1 and the second driver DV2-1.

In FIG. 6B and FIG. 6C, a length LT1 of the second region SEA2 in the first direction DR1 may be determined by a first length LT1-1 of the first driving part GDC1 in the first direction DR1. The length LT1 of the second region SEA2 in the first direction DR1 and the first length LT1-1 of the first driving part GDC1 in the first direction DR1 may be substantially the same.

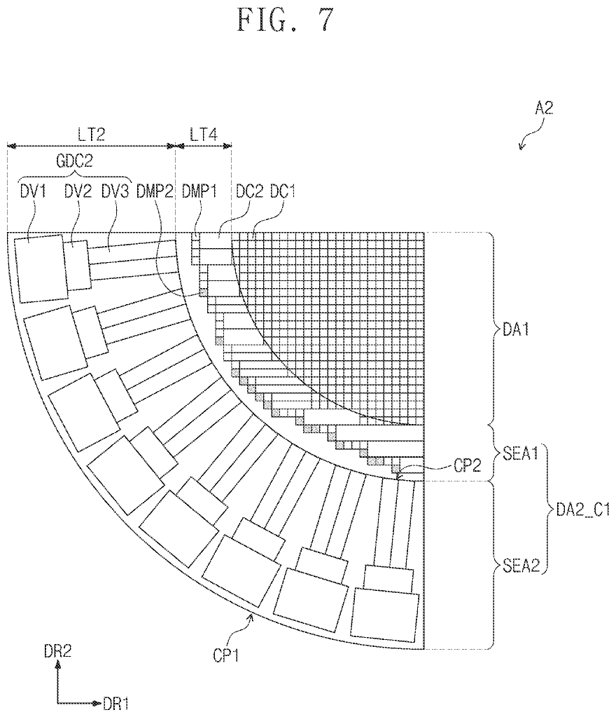

FIG. 7 is an enlarged schematic plan view of region A2 illustrated in FIG. 3. FIG. 8 is a schematic view showing the comparison of an edge region and a corner region according to an embodiment. Referring to FIG. 7 and FIG. 8, the difference in the placement structure and shape between the first and second driving parts GDC1 and GDC2 respectively disposed in the edge region and the corner region may be described.

Referring to FIG. 7, the first pixel driving circuits DC1 may be disposed in the first display region DA1, and the second pixel driving circuits DC2 may be disposed in the first region SEAL On the outer periphery of the second pixel driving circuits DC2, a first dummy pattern DMP1 and a second dummy pattern DMP2 may be disposed. The first dummy pattern DMP1 and the second dummy pattern DMP2 may be disposed for the stability of the placement pattern of the second pixel driving circuits DC2 of the first region SEA1. For example, for the stable driving of the second pixel driving circuits DC2, the first dummy pattern DMP1 and the second dummy pattern DMP2 may be disposed on the outer periphery of the first region SEA1.

Nevertheless, since the first dummy pattern DMP1 and the second dummy pattern DMP2 require an additional space in the first corner region DA2_C1, in order to secure the additional space while uniformly maintaining the outer circumference of the first corner region DA2_C1, the second driving part GDC2 according to an embodiment may have a different placement or shape from that of the first driving part GDC1 of the first edge region DA2_E1. A detailed description will be provided with reference to FIG. 8.

In FIG. 7, at least a portion of the first corner region DA2_C1 has a curved line shape. The outer circumference of the second region SEA2 of the first corner region DA2_C1 may have a first curved line pattern CP1. The outer circumference of the first region SEA1 may have a second curved line pattern CP2. The first curved line pattern CP1 and the second curved line pattern CP2 may have a curvature. The shape and curvature of the first curved line pattern CP1 and the second curved line pattern CP2 may be variously changed.

The second region SEA2 may have an outer boundary line and an inner boundary line. The outer boundary line of the second region SEA2 may be defined as the first curved line pattern CP1. The inner boundary line of the second region SEA2 may be defined as the second curved line pattern CP2.

In an embodiment, the distance between the outer boundary line of the second region SEA2 and the inner boundary line thereof may correspond to the shortest distance LT2 of the second region SEA2 in the first direction DR1 or the second direction DR2.

In FIG. 8, the first driving part GDC1 and the second driving part GDC2 may have different placements and shapes. The first driving part GDC1 and the second driving part GDC2 may equally include first drivers DV1 and DV1-1, second drivers DV2 and DV2-1, and third drivers DV3-1, DV3-2, DV3-3, and DV3-4. However, the first driving part GDC1 may have the same placement and shape of the first driver DV1-1 and the second driver DV2-1, and the second driving part GDC2 may have different placements and shapes of the first driver DV1 and the second driver DV2.

The structure and shape of the first driving part GDC1 may determine the first length LT1 of the second region SEA2 in the first edge region DA2_E1, and the placement and shape of the second driving part GDC2 may determine the second length LT2 of the second region SEA2 in the first corner region DA2_C1.

In an embodiment, the first length LT1 may be greater than the second length LT2. For example, the length of the first driving part GDC1 in the first direction DR1 may be greater than the length of the second driving part GDC2 in the first direction DR1. For example, the first length LT1 may be greater than the second length LT2 by a third length LTS. The third length LTS may be substantially the same as a length corresponding to the difference between the length of the first driving part GDC1 in the first direction DR1 and the length of the second driving part GDC2 in the first direction DR1.

In an embodiment, the first curved line pattern CP1 on the outer periphery of the second region SEA2 in the first corner region DA2_C1 may be the same as the first curved line pattern CP1 on the outer periphery of the second region SEA2 in the first edge region DA2_E1. The first curved line pattern CP1 may define the outer boundary line of the second region SEA2 in the first edge region DA2_E1 and in the first corner region DA2_C1.

The second curved line pattern CP2 on the inner side of the second region SEA2 in the first corner region DA2_C1 may be different from a third curved line pattern CP3 on the inner side of the second region SEA2 in the first edge region DA2_E1. The second curved line pattern CP2 may define the inner boundary line of the second region SEA2 in the first corner region DA2_C1, and the third curved line pattern CP3 may define the inner boundary line of the second region SEA2 in the first edge region DA2_E1. The distance from the first display region DA1 to the inner boundary line of the second region SEA2 in the first edge region DA2_E1 may be shorter than the distance from the first display region DA1 to the inner boundary line of the second region SEA2 in the first corner region DA2_C1. On the contrary, the distance from the first display region DA1 to the outer boundary line of the second region SEA2 in the first edge region DA2_E1 may be the same as the distance from the first display region DA1 to the outer boundary line of the second region SEA2 in the first corner region DA2_C1.

In an embodiment, depending on the difference in positions of the inner boundary line in the first edge region DA2_E1 and in the first corner region DA2_C1, the first region SEA1 in the first corner region DA2_C1 may further include a second sub-region SEA1-2. For example, in the first corner region DA2_C1, the first region SEA1 may include a first sub-region SEA1-1 and a second sub-region SEA1-2. In an embodiment, the second pixel driving circuit DC2 may be disposed in the first sub-region SEA1-1, and the first dummy pattern DMP1 and the second dummy pattern DMP2 may be disposed in the second sub-region SEA1-2.

Referring to FIG. 8, the driving part GDC may include driving lines SWR1 and SWR2. The driving lines SWR1 and SWR2 may be connected to the driving part GDC and a driving unit (not shown) to transmit an electrical signal. For example, the driving lines SWR1 and SWR2 may include the control signal line CSL connected to the pads of the scan driving circuit and the mounting region PDA (see FIG. 3A).

The driving lines SWR1 and SWR2 may include a first driving line SWR1 and a second driving line SWR2. The first driving line SWR1 may be connected to the first driving part GDC1. The second driving line SWR2 may be connected to the second driving part GDC2. The first driving line SWR1 and the second driving line SWR2 may be distinguished from each other based on a boundary BDR between the first edge region DA2_E1 and the first corner region DA2_C1.

The first driving line SWR1 may include a first line WR1-1 connected to the first driver DV1-1, a second line WR2-1 connected to the second driver DV2-1, a third line WR3-3 connected to the third driver DV3-3, and a fourth line WR3-4 connected to a fourth driver DV3-4. In the same manner, the second driving line SWR2 may include a first line WR1 connected to the first driver DV1, a second line WR2 connected to the second driver DV2, a third line WR3-1 connected to the third driver DV3-1, and a fourth line WR3-2 connected to a fourth driver DV3-2.

In an embodiment, the second driving line SWR2 may be disposed farther from the first display region DA1 than the first driving line SWR1. The second driving line SWR2 may move in the first direction DR1 from the first driving line SWR1 based on the boundary BDR between the first edge region DA2_E1 and the first corner region DA2_C1.

In an embodiment, the degree to which the second driving line SWR2 may be farther from the first display area DA1 than the first driving line SWR1 increases as the second driving line SWR2 is closer to the first display region DA1. For example, in the case of the first line WR1 of the second driving line SWR2 and the first line WR1-1 of the first driving line SWR1, the distance thereof from the first display region DA1 may be substantially the same. However, the second line WR2 of the second driving line SWR2 may be disposed farther from the first display region DA1 by a level (e.g., a predetermined or selectable level) than the second line WR2 of the first driving line SWR1. The third line WR3-1 and the fourth line WR3-2 which may be closer to the first display region DA1 than the second line WR2 of the second driving line SWR2 may be disposed to be farther from the first display region DA1 at a level greater than the level than the third line WR3-3 and the fourth line WR3-4 of the first driving line SWR1.

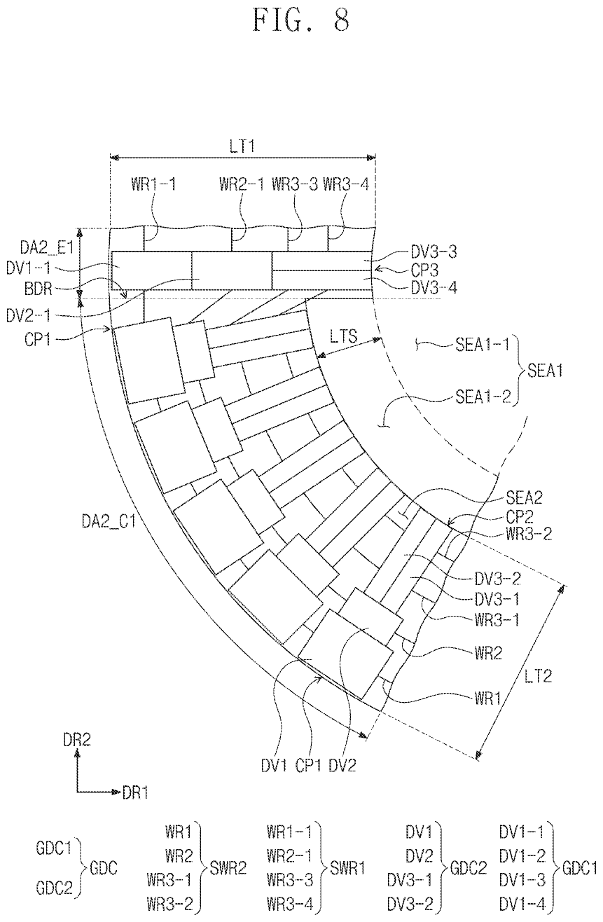

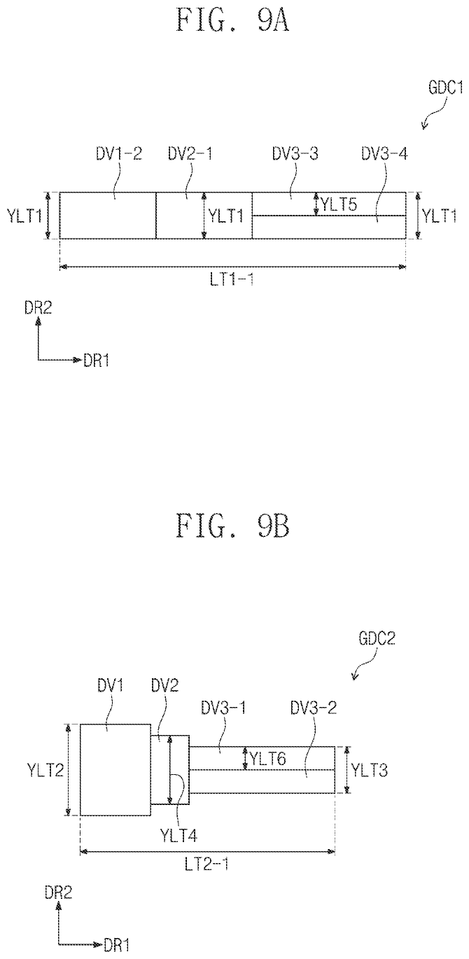

FIG. 9A is a schematic view showing a first driver according to an embodiment. FIG. 9B is a schematic view showing a second driver according to an embodiment. The first driving part GDC1 and the second driving part GDC2 may have substantially the same circuit configuration, but may be different from each other in terms of placement and shape. The first driving part GDC1 and the second driving part GDC2 may be provided with different internal components to have different shapes and different placement structures from each other. Referring to FIG. 9A and FIG. 9B, in the first driving part GDC1 and the second driving part GDC2, the first drivers DV1 and DV1-1 and the second drivers DV2 and DV2-1 may be disposed adjacent to each other in the first direction DR1, the third drivers DV3-1, DV3-2, DV3-3, and DV3-4 may be disposed adjacent to the second drivers DV2 and DV2-1. The third drivers DV3-1, DV3-1, DV3-2, and DV3-4 may be disposed adjacent to each other in the second direction DR2.

The maximum length YLT1 of the first driving part GDC1 in the second direction DR2 may be the same as each of lengths YLT1 of the first driver DV1-1, the second driver DV2-1, and the third drivers DV3-3 and DV3-4 in the second direction DR2. On the contrary, the maximum length of the second driving part GDC2 in the second direction DR2 may be the same as a length YLT2 of the first driver DV1 in the second direction DR2. For example, in the second driving part GDC2, the first driver DV1 has the greatest length in the second direction DR2, and the second driver DV2 has a length YLT4 less than that, and the sum of lengths YLT6 of each of the third drivers DV3-1 and DV3-2 in the second direction DR2 may be less than the length YLT4 of the second driver DV2 in the second direction DR2. FIG. 9B is only an example, and the length YLT4 of the second driver DV2 in the second direction DR2 and a length YLT3 of the third drivers DV3-1 and DV3-2 in the second direction DR2 may be the same as each other. Alternatively, the length YLT2 of the first driver DV1 and the length YLT3 of the third drivers DV3-1 and DV3-2 may be the same as each other.

The shape of the second driving part GDC2 may occupy a larger area in the second direction DR2 toward the outer periphery within the second region SEA2 and may occupy a smaller area toward the inner side therewithin. The shape of the first driving part GDC1 may have a uniform length YLT1 in the second direction DR2 within the second region SEA2.

As the length YLT1 of the first driving part GDC1 in the second direction DR2 is less than the lengths YLT2 and YLT3 of the second driving part GDC2 in the second direction DR2, the length LT1-1 of the first driving part GDC1 in the first direction DR1 may be greater than the length LT2-1 of the second driving part GDC2 in the first direction DR1.

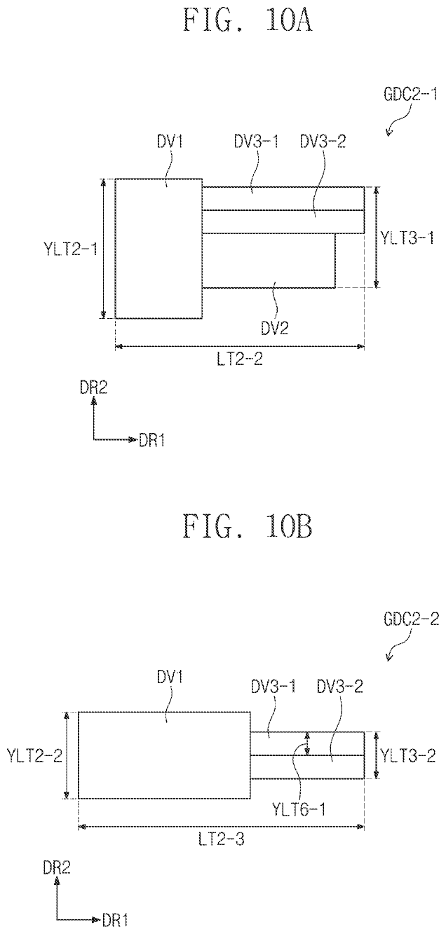

FIG. 10A and FIG. 10B are each schematic views of a second driving part according to another embodiment.

In FIG. 10A, a second driver DV2 of the second driving part GDC2-1 may be disposed adjacent to third drivers DV3-1 and DV3-2 in the second direction DR2. A length LT2-2 of the second driving part GDC2-1 in the first direction DR1 may be less than the length LT2-1 of the second driving part GDC2 in the first direction DR1, the maximum length YLT2-1 thereof in the second direction DR2 may be greater than the maximum length YLT2 of the second driving part GDC2 in the second direction DR2 of FIG. 9B. For example, the shape of the second driving part GDC2-1 may be changed in a manner in which the length in the first direction DR1 is decreased and the length in the second direction DR2 is increased. The sum of lengths YLT3-1 of each of the third drivers DV3-1 and DV3-2 and the second driver DV2 in the second direction DR2 may be less than the length YLT2-1 of the first driver DV1 in the second direction DR2.

In FIG. 10B, a second driving part GDC2-2 may only include a first driver DV1 and third drivers DV3-1 and DV3-2. For example, in the second driving part GDC2-2, a second driver may be omitted. The first driver DV1 serves as a second driver, and the size of the first driver DV1 may increase. A length YLT6-1 of each of the third drivers DV3-1 and DV3-2 in the second direction DR2 may vary in proportion to a length YLT2-2 of the first driver DV1 in the second direction DR2. The sum of lengths YLT3-2 of each of the third drivers DV3-1 and DV3-2 in the second direction DR2 may be less than the length YLT2-2 of the first driver DV1 in the second direction DR2.

A length LT2-3 in the first direction DR1 of the second driving part GDC2-2 of an embodiment, in which the second driver DV2 (see FIG. 9B) is omitted, may be less than the length LT2-1 in the first direction DR1 of the second driving part GDC2 of FIG. 9B.

A display device according to an embodiment may provide a display device with a reduced bezel.

A display device according to an embodiment may secure an inner space in which pixels are disposed and have a reduced bezel by designing the placement and shape of a driving part disposed in a corner region of a display panel differently from the placement and shape of a driving part disposed in an edge region thereof.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device comprising:
a display panel including:
a display region; and
a non-display region adjacent to the display region, the display region including:
a first display region; and
a second display region more adjacent to the non-display region than the first display region, and including an edge region and a corner region, the edge region and the corner region each including a first region and a second region continuously defined, wherein
the display panel includes:
a first pixel disposed in the first display region;
a second pixel disposed in the second display region; and
a driving part disposed in the second region,
the driving part includes:
a first driving part disposed in the edge region; and
a second driving part disposed in the corner region, and
a shape of the first driving part and a shape of the second driving part are different from each other.

2. The display device of claim 1, wherein the display panel further comprises:
a base layer;
a circuit layer disposed on the base layer, and including:
a first pixel driving circuit overlapping the first display region in a plan view;
a second pixel driving circuit overlapping the first region in a plan view; and
a driver overlapping the second region in a plan view; and
a light emission element layer disposed on the circuit layer, and including:
a first light emission region overlapping the first display region in a plan view; and
a second light emission region overlapping the second display region in a plan view.

3. The display device of claim 2, wherein
the first pixel is electrically connected to the first pixel driving circuit, and
the second pixel is electrically connected to the second pixel driving circuit.

4. The display device of claim 3, wherein
the second pixel is disposed in the first region and in the second region, and
the second pixel disposed in the first region and the second pixel disposed in the second region are both electrically connected to the second pixel driving circuit disposed in the first region.

5. The display device of claim 2, wherein an area of the second light emission region is greater than an area of a corresponding first light emission region.

6. The display device of claim 1, wherein
the first driving part has a first length in a first direction,
the second driving part has a second length in the first direction, and
the first length is greater than the second length.

7. The display device of claim 6, wherein
the first driving part has a third length in a second direction intersecting the first direction,
the second driving part has a fourth length in the second direction, and
the third length is less than the fourth length.

8. The display device of claim 1, wherein the first driving part and the second driving part each include a first driver, a second driver, and third drivers.

9. The display device of claim 8, wherein
the first driver and the second driver are disposed adjacent to each other in a first direction, and
the third drivers are disposed adjacent to each other in a second direction intersecting the first direction.

10. The display device of claim 9, wherein the second driver and the third drivers are disposed adjacent in the first direction.

11. The display device of claim 10, wherein a maximum length in the second direction of each of the first driver, the second driver, and the third drivers of the first driver is equal to each other.

12. The display device of claim 11, wherein:
the maximum length in the second direction of the first driver of the second driving part is greater than the maximum length in the second direction of the second driver of the second driving part; and
the maximum length in the second direction of the second driver of the second driving part is greater than the maximum length in the second direction of the third drivers of the second driving part.

13. The display device of claim 1, wherein
the driving part further comprises:
a first driving line electrically connected to the first driving part,
at least one second driving line extended from the first driving line and electrically connected to the second driving part, and
the second driving line is disposed farther from the first display region than the first driving line.

14. The display device of claim 13, wherein
the at least one second driving line includes second driving lines, and
among the second driving lines, a second driving line adjacent to the first display region is disposed farther from the first display region than the first driving line.

15. A display device comprising:
a display panel in which a display region and a non-display region adjacent to the display region are defined on a plane, wherein
the display region includes:
a first display region; and
a second display region more adjacent to the non-display region than the first display region, and including an edge region and a corner region, the edge region and the corner region each includes:
a first region in which a light emission element and a pixel driving circuit electrically connected to the light emission element are disposed;
a second region in which a driving part is disposed, and
a length in a first direction of the second region defined in the edge region is greater than a length in the first direction of the second region defined in the corner region.

16. The display device of claim 15, wherein a length in the first direction of the first region defined in the edge region is less than a length in the first direction of the first region defined in the corner region.

17. The display device of claim 15, wherein
the driving part comprises:
a first driving part disposed in the edge region; and
a second driving part disposed in the corner region, and
a first length in the first direction of the first driving part is greater than a second length in the first direction of the second driving part by a third length.

18. The display device of claim 17, wherein the length in the first direction of the second region defined in the edge region is greater than the length in the first direction of the second region defined in the corner region by the third length.

19. The display device of claim 17, wherein the maximum length in a second direction intersecting the first direction of the first driving part is less than the maximum length in the second direction of the second driving part.

20. The display device of claim 15, wherein
the display panel comprises:
a base layer;
a circuit layer disposed on the base layer, and having the pixel driving circuit and the driving part disposed therein; and
a light emission element layer disposed on the circuit layer, and including the light emission element.

21. The display device of claim 15, wherein
in the corner region, the first region comprises:
a first sub-region; and
a second sub-region defined between the first sub-region and the second region, and
the pixel driving circuit is disposed in the first sub-region.

22. The display device of claim 15, wherein:
a distance from the first display region to an outer boundary line of the second region in the edge region is substantially equal to a distance from the first display region to an outer boundary line of the second region in the corner region; and
a distance from the first display region to an inner boundary line of the second region in the corner region is greater than a distance from the first display region to an inner boundary line of the second region in the edge region.
